(19) United States
(12) Patent Application Publication
(10) Pub. No.: US 2009/0032087 A1
(43) Pub. Date: Feb. 5, 2009

(54) Manufacturing processes for light concentrating solar module

(76) Inventor: Juris P. Kalejs, Wellesley, MA (US)

Correspondence Address: J. SCOTT SOUTHWORTH ATTORNEY AT LAW, P.O. BOX 1287, FRAMINGHAM, MA, 01701, US

(21) Appl. No.: 12/286,025

(22) Filed: Sep. 26, 2008

Related U.S. Application Data
(63) Continuation-in-part of application No. 12/079,437, filed on Mar. 27, 2008.
Application No. 12/079,437 is a continuation-in-part of application No. 12/012,570, filed on Feb. 4, 2008.
(60) Provisional application No. 60/908,750, filed on Mar. 29, 2007.
(60) Provisional application No. 60/888,337, filed on Feb. 6, 2007.

(51) Int. Cl. H01L 31/042; B05D 5/12

(52) U.S. Cl. 136/246; 427/74

(57) ABSTRACT

Solar module manufacturing methods for manufacturing a light concentrating solar module including photovoltaic (PV) cells. The method includes applying an interconnect material to a flexible electrical backplane having preformed conductive interconnect circuitry to form interconnect attachments. The method aligns an array of back contact PV cells with the interconnect attachments. Conductive pathways are formed between the PV cells and the conductive interconnects of the flexible electrical backplane. The method includes providing a light concentrating layer between PV cells that are spaced apart. The method applies an encapsulant material to fill spaces formed between the PV cells and the flexible electrical backplane to form a solar cell subassembly, which is incorporated into the light concentrating solar module.

### RELATED APPLICATION

This application is a continuation-in-part of U.S. patent application Ser. No. 12/079,437, titled “Solar Module Manufacturing Processes,” filed on Mar. 27, 2008, Attorney Reference AMS-002, which claims the benefit of U.S. Provisional Patent Application No. 60/908,750, titled “Solar Module Manufacturing Processes,” filed on Mar. 29, 2007, the entire teachings of both of which applications are incorporated herein by reference.

### BACKGROUND

Solar electric panels, called “modules,” include interconnected solar cells disposed between a front (top) protective support sheet or superstrate and a transparent encapsulant layer, which may be a flexible plastic member or a glass plate that is transparent to most of the spectrum of the sun's radiation, and another transparent encapsulant layer and a back (bottom) support sheet or substrate. The superstrate may be a plastic member or a glass plate. The substrate may be a polymer-based material (for example, a “backskin”) or a glass plate. In one typical manufacturing process for this module, the solar cells have front electrodes in the form of fingers and busbars all located on the front surface of the cell, and back electrodes in the form of soldering “pads” on the back of the cell. The cells are first connected into “strings” by soldering the front electrode busbar (the “n+” electrode) of each cell to the back electrode (the “p+” electrode) pads of the adjacent cell in a sequential manner typically by using conductive ribbons or wires.

In the next process step for manufacturing a solar module, which may be termed the “interconnect (IC) process step,” multiple strings are assembled and enclosed: that is, encapsulated or “packaged” using the abovementioned construction of top and bottom support sheets and encapsulant layers, to protect them against the environment. The encapsulation protects most particularly against moisture, and against degradation from the ultraviolet (UV) portion of the sun's radiation. At the same time, the protective encapsulant is composed of materials which allow as much as possible of the solar radiation incident on the front support sheet to pass through it and impinge on the solar cells. The encapsulant is typically a polymeric material or an ionomer. This polymeric encapsulant is bonded to the front and back support sheets with a suitable heat or light treatment. The back support sheet may be in the form of a glass plate or a polymeric sheet (the backskin). The entire sandwich construction or layered construct of these materials is referred to as a “laminate,” because the materials are bonded in a lamination process. Wiring from the interconnected cells is brought outside of the laminate so that the module can be completed by attachment of a junction box for electrical connections and a frame to support and protect the edges of the laminate.

A modification of the cell design relocates the front n+ electrodes, either busbar alone or both fingers and busbars, to the back of the cell. Improved cell performance is provided by a reduction of the shadowing of parts of the front of the solar cell by removal of the n+ electrode material to the back of the cell. Consequently, the area of the front of the cell that can actively collect the sun's energy is increased.

Some designs of solar cells have the busbars removed from the front of the solar cell to the back. In one approach to solar cell design, all the front electrode metallization; that is, both fingers and busbars, are completely contained on the back of the cell. In one implementation, the fingers are an interdigitated array of n+ and p+ electrodes on the back connected to the busbars, which are designated the back contact solar (BCS) cell. In other approaches to solar cell design, the finger metallization is retained on the front of the cell, but metal strips are extended from the fingers to the back of the cell for purposes of removing the busbar to the back of the cell, hence making all the contacts (n+ and p+) at the back of the cell. The extension of the fingers is accomplished either through vias or holes drilled through the body of the cell, such as the emitter wrap-through (EWT) cell, or by suitable metal “wrapped” around the cell edges, the emitter wrap-around (EWA) cell.

A light reflector approach is used when the solar cells are spaced apart and a light reflecting material is placed in the spaces between the solar cells. Light is reflected upward from the light reflecting material, internally within the module, and some or all of the light may reach the front surface of a solar cell, where the solar cell can utilize the reflected light. U.S. Pat. No. 4,235,643 to Amick describes such an approach for solar cells that are typically circular in shape. The solar module includes a support structure which is formed from an electrically nonconductive material such as a high density, high strength plastic. Generally, support structures are rectangular in shape. Dimensions for a support structure are, in one example, 46 inches long by 15 inches wide by 2 inches deep.

In one traditional light reflector approach the solar cells are arrayed on the top surface of the support structure and connected in series by means of flexible electrical interconnections. Thus, the electrode on the bottom of one solar cell is connected via a flexible end connector to the top bus bar of the next succeeding solar cell. The bus bars connect electrically conductive fingers on the front (top) surface of the cell.

The land areas (that is, the area between the individual solar cells) are provided with facets with light reflective surfaces for reflecting light which normally impinges on the land area at an angle such that the reflected radiation, when it reaches the front surface of the optical medium covering the solar cell array, is internally reflected back down to the front surface of the solar cell array. The array mounted on the support structure must be coupled with an optically transparent cover material. There should be no air spaces between the solar cells and the optical medium or between the land areas and the optical medium. Typically, the optically transparent cover material is placed directly onto the front surface of the solar cells.

### SUMMARY

In one aspect, the invention features a method of fabricating a light concentrating solar module having photovoltaic cells. Each photovoltaic cell has conductive contacts located on a back surface of each photovoltaic cell. The method includes feeding a flexible electrical backplane onto a planar surface. The flexible electrical backplane includes a flexible substrate and a light concentrating layer disposed adjacent to a front surface of the flexible substrate. The flexible electrical backplane has preformed conductive interconnects in contact with interconnect pads exposed on a front surface of the flexible electrical backplane at predetermined locations. The method also includes forming interconnect attachments in electrical contact with the exposed interconnect pads based on applying an interconnect material onto the exposed interconnect pads, and placing the conductive contacts of the photovoltaic cells in an alignment with the predetermined locations of the interconnect pads and in contact with the interconnect attachments. The predetermined locations are determined to provide the alignment for the interconnect pads, the interconnect attachments, and the conductive contacts. The method further includes providing an underlay encapsulant to fill a plurality of spaces formed between the back surfaces of the photovoltaic cells and the front surface of the flexible substrate. The method also includes applying a curing process to the underlay encapsulant solidifying the underlay encapsulant and to the interconnect attachments forming a conductive path from each conductive contact through a respective one of the interconnect attachments to a respective one of the interconnect pads.

In one embodiment, the light concentrating layer is a light reflecting metallic material. In another embodiment, the light concentrating layer includes a diffractive material. The light concentrating layer, in one embodiment, includes light redirecting grooves. In a further embodiment, the light concentrating layer includes a transparent material including light redirecting particles.

In one aspect, the invention features a method of fabricating a light concentrating solar module having photovoltaic cells. Each photovoltaic cell has conductive contacts located on a back surface of each photovoltaic cell. The method includes feeding a flexible electrical backplane including a flexible substrate onto a planar surface. The flexible electrical backplane has preformed conductive interconnects in contact with interconnect pads exposed on a front surface of the flexible substrate at predetermined locations. The method also includes providing a light concentrating layer disposed adjacent to the front surface of the flexible substrate. The light concentrating layer is configured to maintain an exposure of the interconnect pads. The method further includes forming interconnect attachments in electrical contact with the exposed interconnect pads based on applying an interconnect material onto the exposed interconnect pads and placing the conductive contacts of the photovoltaic cells in an alignment with the predetermined locations of the interconnect pads and in contact with the interconnect attachments. The predetermined locations are determined to provide the alignment for the interconnect pads, the interconnect attachments, and the conductive contacts. The method also includes providing an underlay encapsulant to fill spaces formed between the back surfaces of the photovoltaic cells and the front surface of the flexible substrate. The method further includes applying a curing process to the underlay encapsulant solidifying the underlay encapsulant and to the interconnect attachments forming a conductive path from each conductive contact through a respective one of the interconnect attachments to a respective one of the interconnect pads.

In one embodiment, the method includes feeding the flexible electrical backplane from a roll of backplane material and feeding the light concentrating layer from a roll of light concentrating material.

The light concentrating layer, in one embodiment, has a predetermined pattern of apertures aligned to maintain the exposure of the interconnect pads. The light concentrating layer includes encapsulant segments aligned to maintain the exposure of the interconnect pads.

In one aspect, the invention features a method of fabricating a light concentrating solar module having photovoltaic cells. Each photovoltaic cell has conductive contacts located on a back surface of each photovoltaic cell. The method includes feeding a flexible electrical backplane onto a planar surface. The flexible electrical backplane includes a flexible substrate and a light concentrating layer disposed adjacent to a front surface of the flexible substrate, and the flexible electrical backplane has preformed conductive interconnects in contact with interconnect pads exposed on a front surface of the flexible electrical backplane at predetermined locations. The method also includes forming interconnect attachments in electrical contact with the exposed interconnect pads based on applying an interconnect material onto the exposed interconnect pads, and placing the conductive contacts of the photovoltaic cells in an alignment with the predetermined locations of the interconnect pads and in contact with the interconnect attachments. The predetermined locations are determined to provide the alignment for the interconnect pads, the interconnect attachments, and the conductive contacts. The method also includes applying a thermal process to the interconnect attachments forming a conductive path from each conductive contact through a respective one of the interconnect attachments to a respective one of the interconnect pads. The method also includes depositing a liquid underlay encapsulant flowing to fill a plurality of spaces formed between the back surfaces of the photovoltaic cells and the front surface of the flexible substrate. The method further includes applying a curing process to the liquid underlay encapsulant solidifying the liquid encapsulant.

In one aspect, the invention features a method of fabricating a light concentrating solar module having photovoltaic cells. Each photovoltaic cell has conductive contacts located on a back surface of each photovoltaic cell. The method includes feeding a flexible electrical backplane including a flexible substrate onto a planar surface. The flexible electrical backplane has preformed conductive interconnects in contact with interconnect pads exposed on a front surface of the flexible substrate at predetermined locations. The method also includes providing a light concentrating layer disposed adjacent to the front surface of the flexible substrate. The light concentrating layer is configured to maintain an exposure of the interconnect pads. The method further includes forming interconnect attachments in electrical contact with the exposed interconnect pads based on applying an interconnect material onto the exposed interconnect pads, and placing the conductive contacts of the photovoltaic cells in an alignment with the predetermined locations of the interconnect pads and in contact with the interconnect attachments. The predetermined locations are determined to provide the alignment for the interconnect pads, the interconnect attachments, and the conductive contacts. The method also includes applying a thermal process to the interconnect attachments forming a conductive path from each conductive contact through a respective one of the interconnect attachments to a respective one of the interconnect pads. The method includes depositing a liquid underlay encapsulant flowing to fill a plurality of spaces formed between the back surfaces of the photovoltaic cells and the front surface of the flexible substrate. The method further includes applying a curing process to the liquid underlay encapsulant solidifying the liquid encapsulant.

In one embodiment, the method includes feeding the flexible electrical backplane from a roll of backplane material and feeding the light concentrating layer from a roll of light concentrating material. The light concentrating layer, in one embodiment, has a predetermined pattern of apertures aligned to maintain the exposure of the interconnect pads. In another embodiment, the light concentrating layer includes encapsulant segments aligned to maintain the exposure of the interconnect pads.

In one aspect, the invention features a light concentrating solar module including a transparent front cover, photovoltaic cells, a back cover, a light transmitting encapsulant, a light concentrating layer, a flexible electrical backplane, and interconnect attachments. The transparent front cover has a front surface and a back surface. Each photovoltaic cell has one front surface facing the transparent front cover and one back surface facing away from the transparent cover. Each photovoltaic cell has back contacts on each back surface thereof. The back cover is spaced apart from and substantially parallel to the transparent front cover. The photovoltaic cells are disposed between the transparent front cover and the back cover. The light transmitting encapsulant is disposed between the transparent front cover and the back cover. The light concentrating layer disposed between the photovoltaic cells and the back cover. The transparent front cover transmits light through the transparent front cover and is incident on the light concentrating layer in regions between the photovoltaic cells. The light concentrating layer directs the light towards the transparent front cover, and the front surface of the transparent front cover internally reflects the light back towards the photovoltaic cells. A flexible electrical backplane includes a flexible substrate and conductive interconnects preformed thereon in a predetermined pattern. The interconnect attachments are each disposed between one of the conductive interconnects and one of the back contacts of one of the photovoltaic cells.

In one embodiment, the flexible electrical backplane includes the light concentrating layer. The light concentrating layer is provided in the regions between the photovoltaic cells adjacent to the flexible electrical backplane. In another embodiment, the light concentrating layer is a light reflecting metallic material. The light concentrating layer, in another embodiment, includes a diffractive material. In one embodiment, the light concentrating layer includes light redirecting grooves. In another embodiment, the light concentrating layer includes a transparent material including light redirecting particles. In a further embodiment, the flexible substrate has windows disposed adjacent to the back surfaces of the photovoltaic cells. Each window is adjacent to a respective one of the photovoltaic cells.

In one embodiment, the light transmitting encapsulant includes an overlay layer of transparent material disposed adjacent to the back surface of the transparent front cover and an underlay layer of transparent material disposed adjacent to the back surfaces of the solar cells. The overlay layer of transparent material includes one or more encapsulating sheets adjacent to the front surfaces of the solar cells, and the overlay layer also includes an additional layer of encapsulant disposed between the back surface of the transparent front cover and the one or more encapsulating sheets. The additional layer has a density less than the transparent front cover, and replaces a volume of the transparent front cover equal to a volume of the additional layer.

In another embodiment, the conductive interconnects and the light concentrating layer form intervals between the conductive interconnects and the light concentrating layer. The intervals provide an electrically insulating separation between the conductive interconnects and the light concentrating layer; and the intervals provide areas of moisture permeability for moisture flow between the light transmitting encapsulant and the flexible electrical backplane.

The light concentrating solar module, in another embodiment, includes encapsulant segments disposed adjacent to the back surfaces of the solar cells. The encapsulant segments provide encapsulating material adjacent to the solar cells and provide moisture permeability between the light transmitting encapsulant and the flexible electrical backplane.

### BRIEF DESCRIPTION OF THE DRAWINGS

The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 is a schematic side view of a solar cell subassembly illustrating solar cells in contact with a flex-based interconnect system, according to the principles of the invention.

FIG. 2 is a flowchart of a module fabrication procedure utilizing a flexible electrical backplane and providing soldering and ultraviolet light processing, in accordance with the principles of the invention.

FIG. 3 is a flowchart of a module fabrication procedure utilizing a flexible electrical backplane and providing thermal processing, in accordance with the principles of the invention.

FIG. 4A is a side view of a flex-based interconnect system in accordance with the principles of the invention.

FIG. 4B is a plan view of the flex-based interconnect system of FIG. 4A.

FIG. 5A is a side view of a solar cell subassembly including a flex-based interconnect system for an emitter wrap-through (EWT) application, according to the principles of the invention.

FIG. 5B is a plan view of the solar cell subassembly of FIG. 5A.

FIGS. 6A and 6B are exploded side views of a partial solar module illustrating windows in a flexible substrate of the flexible electrical backplane.

FIG. 7 is a side view of a solar electric module including the flex-based interconnect system, in accordance with the principles of the invention.

FIG. 8 is a side view of a light concentrating solar module with an integrated light concentrating layer, in accordance with the principles of the invention.

FIG. 9 is a side view of a light concentrating solar module with a patterned light concentrating layer, in accordance with the principles of the invention.

FIG. 10 is an overhead plan view of a patterned light concentrating layer with apertures, in accordance with the principles of the invention.

FIG. 11 is an overhead plan view of a patterned light concentrating layer with apertures and an encapsulant segment, in accordance with the principles of the invention.

FIG. 12 is a flowchart of a module fabrication procedure utilizing a flexible electrical backplane and light concentrating layer, with soldering and underlay curing, in accordance with the principles of the invention.

FIG. 13 is a flowchart of a module fabrication procedure utilizing a flexible electrical backplane and light concentrating layer, with thermal processing, in accordance with the principles of the invention.

### DETAILED DESCRIPTION

In brief overview, the present invention relates to an improved method for manufacturing solar modules for use with solar cells where all or part of the front electrode metallization is located on the back of the solar cells: for example, the back contact cell (BCS), the emitter wrap-through cell (EWT), and/or the emitter wrap-around cell (EWA). The present invention also relates to improved material for use with the manufacturing process, including a flexible electrical backplane that includes a flexible substrate and preformed electrical circuits for contact with the electrodes (typical both n+ and p+ electrodes) located on the back of the solar cells.

Modification of the cell design, away from the conventional metallization on the front of the solar cells, requires changes in the conventional assembly process of the module materials and the design and materials selection of the module. In one embodiment, the approach of the invention provides for a revised set of fewer manufacturing steps for modules, for use with solar cells where the front n+ electrodes, either the busbar alone or both fingers and busbars, are relocated to the back of the solar cell to form an interdigitated array together with the p+ electrode (which is typically already located on the back of the solar cell). The approach of the invention provides materials of construction, for example, the flexible electrical backplane, and means whereby they are assembled in a module, such as automatically feeding the flexible electrical backplane 14 from a roll of such material. The manufacturing approach of this invention reduces labor intervention when used in the production processes for modules including solar cells which are not of the front contact design. The benefits which are gained include the simplified manufacturing and improved performance for a comparable solar cell material.

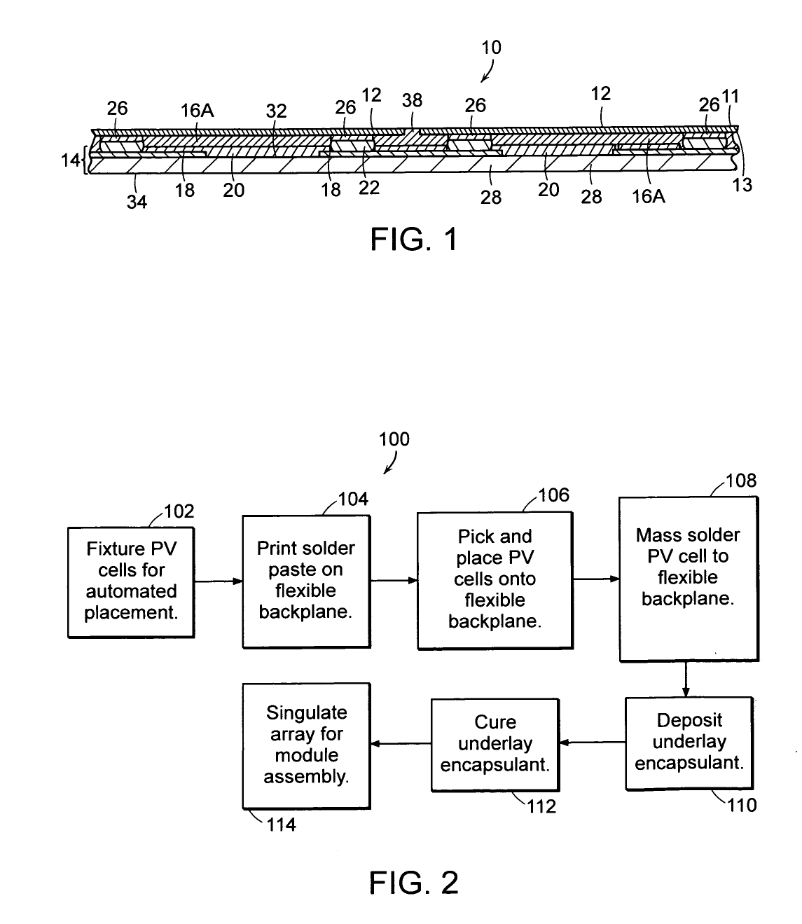

FIG. 1 is a schematic side view of a solar cell subassembly 10 illustrating photovoltaic cells (designed generally by the reference numeral 12) in contact with a flex-based interconnect system, according to principles of the invention. The photovoltaic cells 12 are also termed “solar cells.” In one embodiment, the photovoltaic cells 12 have a thickness of 0.1 to 0.3 millimeters.

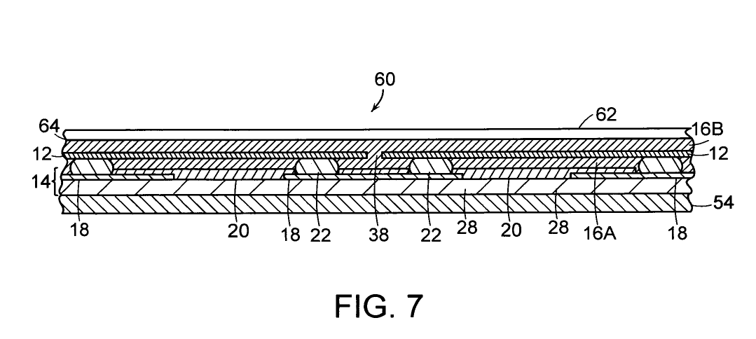

The solar cell subassembly 10 is a partial module because it does not include a front or top layer of encapsulant and/or the front cover of glass or other transparent material, which can be included in a finished module. A solar electric module can be formed, when the encapsulant and front cover are layered with the solar cell subassembly 10, optionally with other layers of materials (for example, layers of encapsulant and/or a back cover), and subjected to a thermal process, lamination process, or other manufacturing process to form the module (see FIG. 7). The solar cell subassembly 10 includes a flexible electric backplane 14, encapsulant 16A (designated generally by reference numeral 16), and interconnect attachments (designated generally by the reference numeral 22) of interconnect material. The flexible electric backplane 14 includes conductive interconnects (designated generally by the reference numeral 18), a cover coat 20, and a flexible substrate 28. The flexible electric backplane 14 has a thickness, in one embodiment, or about 25 microns to about 200 microns. In some embodiments, a cover coat 20 is not required. The interconnect attachments 22, as used herein, are also termed “conductive tabs” or “electrical tabs.”

The flexible substrate 28 is a flexible cloth-like material made of a suitable material (for example, a polymer based material, such as a polyimide material). The encapsulant 16 is a protective light transmitting material that provides protection again physical damage and UV damage. In one embodiment, the encapsulant 16 is a polymer based material; for example, ethyl vinyl acetate (EVA). In other embodiments, the encapsulant 16 is composed of other suitable transparent materials, such as plastic materials, an ionomer material, silicon rubber, or other suitable materials.

The conductive interconnects 18 are patterns of electrically conductive materials integrally included in the top surface 32 (surface facing the photovoltaic cells) of the flexible electric backplane 14. In some embodiments, the conductive interconnects 18 include one or more electrically conductive metals, such as copper, aluminum, silver, gold, and/or other suitable metals, as well as related metallic alloys. In other embodiments, the conductive interconnects 18 are composed of one or more other electrically conductive materials, such as a conductive plastic or polymeric material including particles of a conductive metal or other electrically conductive material.

The cover coat 20 covers the layer of conductive interconnects 18, allowing openings for contact between the conductive interconnects 18 and the interconnect attachments 22. The interconnect attachments 22 enable electrical conduction with conductive contacts (designated generally by the reference numeral 26), also referred to herein as “electrodes,” located on the back surface 13 (surface facing the flexible electrical backplane 14) of the photovoltaic cells 12. The interconnect attachments 22 are composed of one or more interconnect materials that provide electrically conductive paths between the photovoltaic cells 12 and the conductive interconnects 18; for example, solder, electrically conductive adhesive, other suitable material, or combination of materials. In one embodiment, if the interconnect attachments 22 are a conductive adhesive, then the cover coat is, for example, a polyimide material. If, in one embodiment, the interconnect attachments 22 are solder, then the cover coat 20 is a solder mask, and the cover coat 20 is, for example, an epoxy material. In one embodiment, the conductive interconnects 18 are based on a material that is not solder wettable, such as nickel or a conductive material plated with nickel, and a cover coat 20 is not required. In various embodiments, a cover coat 20 is not required if the conductive interconnects 18 are based on a conductive adhesive or conductive ink.

The approach of the invention does not require the spacing of interconnect attachments 22 to be evenly spaced. The positioning of the interconnect attachments 22 is predetermined to align with the conductive contacts 26 so as to form the electrically conductive path between each PV cell 12 and the conductive interconnects 18.

In one embodiment, a back sheet of encapsulant (not shown in FIG. 1) is placed adjacent to the back or bottom surface 34 of the flexible electrical backplane 14 (that is, the surface facing away from the solar cells 12); and a protective back cover (not shown in FIG. 1) is placed adjacent to the back sheet of encapsulant. In one embodiment, the back cover is a backskin.

In one embodiment, the approach, as shown in FIG. 1 can be used with photovoltaic solar cells 12 such as the BCS-type cell for which all the front electrodes are relocated to the back of the cell are illustrated in FIG. 1. With suitable modifications it is also possible to use the manufacturing processes of the invention with other photovoltaic cells 12 that utilize the structure of unconventional metal (that is, electrode) configurations; for example, for the class of EWT and EWA photovoltaic cells.

Several of these cell designs are further described in U.S. Pat. Nos. 5,468,652 and 5,972,732 (both by James Gee et al), which are provided by way of example and not limitation and are incorporated herein by reference. In the examples of U.S. Pat. Nos. 5,468,652 and 5,972,732, the n+ and p− electrodes may be formed partially on the front of the photovoltaic cell and then extended to the back of the cell through a multiplicity of vias or holes drilled through the cell material. U.S. Pat. No. 5,468,652 describes a method of making a back contacted solar cell 12. A solar cell 12 is produced that has both negative and positive current-collection grids positioned on the back side of the photovoltaic cell 12, by using vias drilled in the top surface 11 of the cell 12 to transmit the current from the front side current-collection junction to a back-surface grid. The approach is to treat the vias to provide high conductivity and to isolate each via electrically from the rest of the cell 12. On the back-side of the cell 12, each via is connected to one of the current-collection grids. Another grid (of opposite polarity) connects to the bulk semiconductor with doping opposite to that used for the front-surface collection junction. To minimize electrical resistance and carrier recombination, the two grids are interdigitated and optimized.

U.S. Pat. No. 5,972,732 describes methods for assembly that use back-contact photovoltaic cells 12 that are located in contact with circuit elements, typically copper foil, which is affixed to a planar support, typically with the use of a conductive adhesive. The photovoltaic cells 12 are encapsulated using encapsulant materials such as EVA. This approach allows the connection of multiple cells 12 in an encapsulation process, in a one-stage soldering process.

By way of example but not limitation the modules may take the form of those described and illustrated in U.S. Pat. Nos. 5,478,402 (by Jack Hanoka), 5,972,732 (by James Gee et al, 1999), which is described above, and 6,133,395 B1 (by Richard Crane et al, 2001), all of which are incorporated herein by reference, wherein designs of photovoltaic cells 12 which may be used are constructed with a plurality of electrodes for positive and negative charge collection either both on the front and back of the solar cells, or, alternately, entirely on the back of the solar cells, as in the BCS cell.

In the approach used by U.S. Pat. No. 5,478,402, an array of electrically interconnected photovoltaic cells is disposed in an assembly between two sheets of supporting material (front and back). The assembly is encapsulated by using thermosetting plastic composed of ionomer in layers to the front of the cells and to the back of the cells. Each solar cell is connected to the next adjacent solar cell by a ribbon-like conductor. Each conductor is soldered to a back contact of one cell and is also soldered to a front contact of the next adjacent cell. In this approach, a string of cells is constructed. The whole interconnected array has terminal leads that extend out of the module.

In the approach used by U.S. Pat. No. 6,133,395 B1, foil interconnect strips are used to connect photovoltaic cells, which are placed next to each other or relatively close to each other. The foil interconnect strips are soldered or welded to contacts on the adjacent cells, or between a cell and a bus. Thus the adjacent cells are connected by the foil interconnect strips to the same surface of the adjacent cell (for example, the connection is from the front surface of one cell to the front surface of the adjacent cell). The peripheral interconnects (on the periphery of the array of cells) have a special structure, such as a flattened spiral to avoid problems of buckling or deformation that may occur for this type of solar module.

The conventional module manufacturing process proceeds as follows: The solar electric module is manufactured by assembling a configuration of solar cells in a grid-like pattern in which the solar cells are interconnected by a network of conducting strips or wires, called “tabbing.” The tabbing is first solder coated and then flux coated in order to provide desired soldering properties when heated to the solder melt temperature. The grid configuration is chosen so this cell array can deliver a pre-selected set of currents, voltages and Watts in the output product. In order to assemble the module array, cells are first connected in series in units called “strings.” To assemble the strings, cells are individually placed on a processing unit called a “stringer” or “assembler,” which may also be termed “the interconnect (IC) unit.” Individual tabbing strips, already pre-cut to desired lengths (of dimensions of the order of those of the cells to be soldered), solder-coated and fluxed, are each positioned individually on cell surfaces, which have designed contact locations. The contact locations are the n+ busbar on the front of the cell, and multiple islands or strips of silver (or silver alloys) on the back. The tabbing is held down by mechanical clamps, which are usually automatically actuated. While the cells and tabbing are clamped in the abovementioned manner, a heater, such as an IR (infrared) lamp for example, heats the solder to the melting temperature to enable the formation of a solder bond in multiple locations. The locations are typically all along the front busbar, and at 6 through 12 locations or pads on the back of the conventional solar cell. Strings of up to 10 through 12 cells are typically incorporated into a single laminated solar cell module, and individual strings may be combined in series by wires or tabbing to form an array of up to 72 cells in a sequential process. By example, in the latter case, a module configuration of 72 cells in series includes six individual strings, each of 12 cells, connected by tabbing strips across the ends of adjacent strings alternating from end to end. In order to complete the electrical grid, a copper wire “harness” is used to electrically connect to the strings within the laminate and to act as a continuous connection to the outside of the laminate is used. The copper wire harness can be used both when there is only one string, or in the case when there are multiple strings connected as above. The copper wire harness is assembled and placed on and soldered to the ends of the cell strings through solder joints.

In the conventional manufacturing process for a solar module, once a string of solar cells has been completed, the next step of the conventional process is to bring the string to a “layup” station location in the assembler. At the layup station, a mechanical pick and place robot holding an entire string is used to integrate the strings into the desired electrical grid with materials needed to complete the laminated solar cell module; that is, typically the front cover, the encapsulant layers, and the back cover.

Further details of the conventional process for manufacturing solar modules are provided as follows: In the back cover assembly step, a back cover (for example, backskin) is placed on a table that is part of an assembler device. Then, a back layer of encapsulant is placed on the back cover. Strings of solar cells are assembled, as described elsewhere herein, including the tabbing wiring or ribbons that connect adjacent solar cells. The strings must be handled and indexed to pre-assigned locations on the encapsulant layer. The string wiring must be implemented through individual placing of the copper wiring harness and soldering steps. Then a further layer of encapsulant and a front cover are placed on top of the solar cell strings. The assembly now typically includes the back cover, back or bottom layer of encapsulant, strings of solar cells, front or top layer of encapsulant, and front cover. The assembly is subjected to a lamination process using high pressure and temperature sufficient to melt the encapsulant to form a solar cell module. The assembly is then subject to testing.

In the approach of the invention, an integrated cell assembly process, for example for the BCS cell module, has a high yield and high reliability relative to the conventional process. The conventional process, as described elsewhere herein, includes individual soldering, fluxing and handling/placing steps for the many tabbing strips and harnesses which are interconnected typically by a hot bar soldering method. The process of the present invention eliminates the individual tabbing strips and step-by-step soldering of the solar cells and cell strings usually done in a multiplicity of stations in the conventional approach. A single pre-formed material sheet or flexible substrate 28 is provided for the backplane 14 that integrally includes the conductive interconnects 18 and is flexible.

In one embodiment, the process introduces material sheets such as the back cover (for example, backskin) and encapsulant from rolls, and utilizes high speed assembly of the cells 12 using automated pick and place (or robotic) assembly equipment capable of handling both the smaller solar cells 12 and panels of glass (for example, for a front cover for the module). In one embodiment, if large panels must be manipulated, a robotic assembly equipment is appropriate; for example, for large panels of glass suitable for use as front covers for modules with large number of PV cells 12 (for example, 72 cells 12). The integrated flexible electrical backplane 14 includes the flexible substrate 28, which is a flexible material, with properties of a cloth, (also termed the “flex material” or “Flex”). The flexible material, in one embodiment, can be a polymeric material, a paper or paper-like material, or cloth (woven or nonwoven) Attached to the front surface 32 of the flexible substrate 28 of the flexible electrical backplane 14 are the finger and the n+ and p+ electrode circuits, which are utilized for the primary wiring structure that connects to the contacts 26 on the photovoltaic cells 12 (for example, back contacts 26 on BCS cells). The assembled PV cells are interconnected using mass interconnection techniques; for example, reflow soldering, or, alternatively, conductive adhesive curing.

An improved manufacture of the module is possible through use of the metallized flexible sheets of material composed of a flexible cloth-like material, when the flexible material is adapted and configured in patterns (for example, conductive interconnects 18) as described for example for the flexible electrical backplane 14 of FIG. 1. The use of the flexible electrical backplane 14 can reduce assembly time, assembly labor and simplify the interconnect processes for cells 12 and the lamination process for encapsulation (or other process used for encapsulation). Accordingly, a manufacturing method uses the flex materials in the flexible substrate 28 that can be supplied to the process station in a roll-out format. The flex materials, as in the flexible electrical backplane 14, already contain the embedded conducting electrode material (for example, conductive interconnects 18) to simplify manufacturing of solar electric modules and replace conventional interconnecting steps for cells 12 by automated pick and place positioning operations. Various back plane interconnect materials can be utilized, for example, in the flexible electrical backplane 14. One example is a polyimide based flexible interconnect substrate (for example, flexible substrate 28) with copper laminated interconnects 18 patterned with standard photomask and wet etching techniques.

Further details for one embodiment of the invention are now described. A flexible electrical backplane 14 is used. In one embodiment, the flexible substrate 28 of the flexible electrical backplane 14 is coated with the patterned metal films. The flexible electrical backplane 14 can also become the back cover, if a moisture barrier coating is applied to the back-side or outside (that is, back surface 34) of the flexible electrical backplane 14. In one embodiment, conducting epoxies can be combined with copper to form the pre-pattern conductors (for example, conductive interconnects 18).

In one embodiment, a back cover sheet, an encapsulant sheet (that is, a back sheet of encapsulant), and the flexible electrical backplane 14 including the electrodes (for example, conductive interconnects 18) are brought into the assembler device by a roller feed in one automated step. In a particular embodiment, the back cover sheet (for example, backskin) is provided as one roll of material, the encapsulant sheet is provided as another roll of material, and the flexible electrical backplane is provided as another roll of material. The assembler device is configured to hold the three rolls of material and feed them simultaneously into the assembler device in an automated step so that the back cover sheet is the bottom layer, the back sheet of encapsulant is the next layer, and the flexible electrical backplane 14 is the next layer.

The advantage is provided of a one-step production of a back cover assembly including the back cover sheet, a back sheet of encapsulant, and the flexible electrical back plane 14 (including conductive interconnects 18). The patterned metal electrode (conductive interconnects 18 included in the flexible electrical backplane 14) has the advantage of eliminating the individual cell tabbing strips of the convention approach, which is prone to failure in thermal cycling caused by differential thermal expansion stress when assembled by a conventional module manufacturing process.

In one embodiment, fluxless solder systems are provided that are not typically used in the photovoltaic industry, which has the advantage of preventing flux from being released from the solder into the solar cell module, which can cause degradation of materials and degradation of reliability due to the flux residue remaining within the finished solar cell module.

Regarding the cell placement step of the manufacturing process, the approach includes the preformed flexible electrical backplane 14, which, in one embodiment, contains electro-plated and solder dipped copper pattern (for example, conductive interconnects 18) etched to the designed configuration to match the photovoltaic cell back contacts as one complete unit. All of the locations covering an entire module of photovoltaic cells (for example, 72 cells) can be soldered with one step of heating. The approach of the invention is not limiting of the number of cells that can be included in a solar module. The approach of the invention eliminates individual tabbing strip handling, placement and soldering, thus enhancing bond quality. The approach of the invention also reduces thermal stresses in wiring as a result of the flexible material of the flexible substrate 28 of the flexible electrical backplane 14 and circuit compliance.

In one embodiment of the invention, a liquid encapsulant 16A is used with an ultraviolet (UV) cure to solidify the liquid encapsulant. In the manufacturing process for various embodiments, a one step approach is provided that combines soldering with the UV cure, or a one step approach that includes thermal processing of the interconnect attachments 22 (for example, conductive adhesive) and the encapsulant 16A. This approach has the advantage of eliminating the conventional individual steps of soldering individual conductive ribbons or wires between adjacent solar cells and then laminating. The approach of the invention, in one embodiment, also has the advantage of eliminating the pressure aspect of the lamination step, which can cause failures, and is particularly critical in obtaining a high yield of successfully produced solar cell modules when using thin cell wafers. The thin cell wafer typically has a thickness of about 150 microns.

FIG. 2 is a flowchart of a module fabrication procedure 100 utilizing a flexible electrical backplane 14, in accordance with the principles of the invention. In step 102, the PV cells 12 are fixtured or placed onto an automated pick and place robotic device to provide for an automated placement of the cells 12 onto the partially assembled module in a later step of the procedure (see step 106). Then, the flexible electrical backplane 14 is fed or positioned onto a table or planar surface (not shown in FIG. 1) of an assembler device. For example, the flexible electrical backplane 14 is unrolled in an automated process onto the table from a roll of backplane 14 material attached to or available to the assembler device. In one embodiment, the backplane 14 material is automatically sized to a predetermined size (for a given size module), for example, the backplane 14 material is cut to the appropriate predetermined size. In another embodiment, the singulation of the module or partially assembled module occurs at step 114 of the procedure 100.

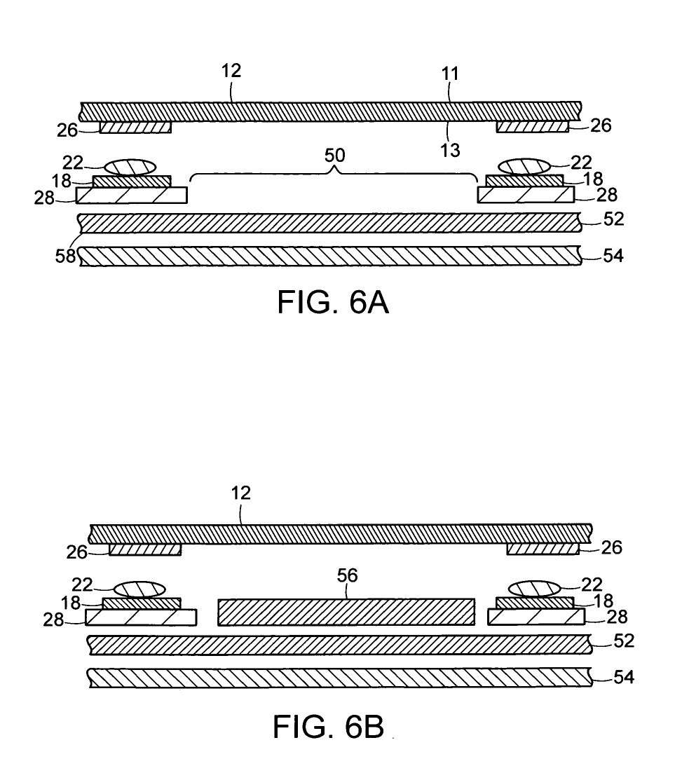

In one embodiment, three rolls of material are available to the assembler device. One roll is a back cover (for example, 54 in FIG. 6A) another roll is a back sheet of encapsulant (for example, 52 in FIG. 6A), and another roll is the backplane 14 material. These rolls are automatically and concurrently fed into the assembler so that the back cover (for example, backskin), is the bottom layer, the back sheet of encapsulant is the next layer, and the backplane 14 material is the top layer. Then the three layers are sized to a predetermined size, in one embodiment. In one embodiment, one or more strips of encapsulant (for example, 56 in FIG. 6B) can be fed concurrently from a roll of material (see, for example, the discussion for FIG. 6B). In another embodiment, a back sheet of encapsulant (for example 52 in FIG. 6B) can include a protrusion or “rib” of encapsulant material (as described, for example, for FIG. 6B).

In one embodiment, the flexible electrical backplane 14 is fed or positioned onto the planar surface of the assembler device as sheets of backplane material. In another embodiment, the flexible electrical backplane 14 is fed from precut rolls of backplane material.

In step 104, the procedure prints a solder paste on the flexible electrical backplane 14; for example in a stencil printing process that applies the solder paste to predetermined portions of the conductive interconnects 18. In one embodiment, the process includes printing or providing a cover coat (or solder mask) 20 before applying the solder paste. The solder paste is applied to form interconnect attachments 22 composed of an interconnect material (for example, solder paste) at predetermined positions that are located to align with the back contacts 26 of the PV cells 12, which occurs during step 106 when the PV cells 12 are placed onto the flexible electrical backplane 14.

In one embodiment, a conductive adhesive or conductive ink can be printed or applied to the flexible electrical backplane 14 to form the interconnect attachments 22. In various embodiments, a syringe and needle approach is used to deposit (or dispense) the interconnect material to form the interconnect attachments 22. A pump or pressure approach is used to apply the interconnect material (for example, solder paste, conductive adhesive, conductive ink, or other suitable material) to the flexible electrical backplane 14.

In step 106, the procedure 100 places the PV cells 12 already fixtured in step 102 onto the flexible electrical backplane 14 so the back contacts on the PV cells 12 align with the interconnect attachments 22. In one embodiment, the placement of the PV cells 12 is performed by an automated pick and place device. In one embodiment, this device is an automated pick and place machine. In another embodiment, this device is a placement robot, for example a gantry robot or XY robot.

In step 108, the procedure 100 mass solders the PV cells 12 to the flexible electrical backplane 14. In one embodiment, heat is provided by an IR (infrared) lamp to melt solder in the interconnect attachments 22. In various embodiments, heat is provided by convection heating, microwave heating, or vapor phase (or vapor phase flow) heating (that is, a liquid vapor at a controlled temperature). In one embodiment a lead free solder is used. In another embodiment, a fluxless solder is used. In another embodiment, the interconnect attachments 22 are a conductive adhesive, and heat is provided to cause the conductive adhesive to set. Generally, the thermal processing of the interconnect attachments 22 is in the range of 80 degrees centigrade to 250 degrees centigrade, which covers a range suitable for various types of solder. In one embodiment, if a solder is used, the solder is a low temperature solder, for example, indium. For conductive adhesive, the thermal processing can be in the range of 80 degrees centigrade to 180 degrees centigrade, with a typical range of 120 degrees centigrade to 150 degrees centigrade.

In step 110, an underlay encapsulant 16A is deposited or dispensed. In one embodiment, the underlay encapsulant 16A is a liquid encapsulant that is deposited or dispensed in gaps 38 between the PV cells 12, so that the liquid encapsulant 16A flows into spaces between the solar cells 12 and the flexible electrical backplane 14. In one embodiment, the alignment of the interconnect pads 24 and interconnect attachments 22 insure that the solar cells 12 in an array are positioned such that there are sufficient gaps 38 between the solar cells 12 to allow liquid encapsulant 16 to flow between the solar cells 12 in order to reach the spaces between the solar cells 12 and the flexible electrical backplane 14. In one embodiment, vertical barriers are placed around the partial module (as assembled in steps 102 through 108) to insure that the liquid encapsulant 16 does not leak out. In one embodiment, the liquid encapsulant is deposited or dispensed by an automated syringe and needle approach, using one or more syringes and needles.

In one embodiment, the liquid encapsulant 16 covers the top or front surface 11 of the PV cells 12 (the surface facing away from the flexible electrical backplane 14); forming a front or top encapsulant layer (for example, see 16B in FIG. 7). In one embodiment, a top cover sheet (for example, glass) 62 (see FIG. 7) and/or encapsulant layer is placed on top of the liquid encapsulant or PV cells 12 before the curing step (step 112).

In one embodiment, the underlay encapsulant 16A is one or more sheets of encapsulant material layered under the back surface 13 of the PV cells 12 and/or layered beneath the flexible backplane 14. In one embodiment, the flexible substrate 28 has windows (also termed “openings,” “cut-outs,” or “holes”) for parts of the flexible electrical backplane 14 that do not have conductive interconnects 18 embedded or included in the flexible electrical backplane 14. The windows allow for the encapsulant 16 to flow into spaces underneath the PV cells 12. In one embodiment, strips of encapsulant 56 can be provided to insure that the spaces beneath the PV cells 12 are fully filled with encapsulant 16 (see FIGS. 6A and 6B).

In step 112, the underlay encapsulant 16A is cured (for example, by UV light, a thermal process, a microwave process, or other suitable process) to cause the encapsulant 16A to solidify. The windows allow UV light to reach an encapsulant 16A that requires UV light to cure the encapsulant 16A. In one embodiment, UV light is provided to the back side of the solar cell subassembly 40, and is incident on the encapsulant 16A through the windows (for example, before an opaque back cover is applied that would block the transmission of UV light). In one example, the UV light is provided by UV lamps through a transparent planar surface that the solar cell subassembly 40 is disposed upon. In one embodiment, the UV light is provided for about one to about two minutes to effect the cure of the encapsulant 16A.

In one embodiment, a UV light approach is used with liquid encapsulant 16 for a partial solar electric module that is assembled in a reverse manner than what is shown in FIG. 1 (that is, the PV cells 12 would be at the bottom and the flexible substrate 28 at the top). In this assembly approach, a front cover (for example, glass) is placed on a planar surface of an assembler device, then other layers are placed on the front cover; for example, a layer of encapsulant followed by PV cells 12. In this approach, interconnect attachments 22 are attached to the exposed conductive contacts 26 on the back surface 13 of the PV cells 12, which is facing upward because this approach has reversed the orientation of the PV cell 12 from what is shown in FIG. 1. A flexible backplane 14 is provided with a flexible substrate 28 that has one or more windows 50 (see FIG. 6A) in the flexible substrate 28. In this approach, a liquid encapsulant 16A is provided that flows into the space indicated by the window 50. The liquid encapsulant 16A is cured by UV light provided by UV lamps located to provide the UV light through the window 50 so that the UV light is incident on the liquid encapsulant 16A.

In one embodiment, the underlay encapsulant 16A, as shown in FIG. 1, can be cured by a thermal process. For example, sheets and/or strips of EVA encapsulant (for example, back sheet of encapsulant 52 and strips of encapsulant 56 in FIG. 6B) can be cured at about 140 through about 155 degrees centigrade for about 6 minutes, or cured at about 139 degrees centigrade for about 12 minutes. In another embodiment, the underlay encapsulant is cured by a microwave process. In another embodiment, the underlay encapsulant 16A is first treated with UV light to initiate a curing process, and then the curing is completed with a thermal process.

If a front cover (for example glass) 62 (not shown in FIG. 1) is placed over the PV cells 12 and encapsulant (for example, front sheet of encapsulant 16B in FIG. 7) provided between the front cover 62 and the PV cells 12, before step 112, then the front cover can be bonded to the encapsulant 16 by the curing process of step 112. In this approach, a solar module 60, as shown for example in FIG. 7, is produced.

In step 114, the procedure 100 singulates the solar cell subassembly 10 for module assembly. The solar cell subassembly 10 includes the flexible electrical backplane 14 attached (for example, soldered) to the PV cells 12, and the cured encapsulant 16A. In one embodiment, the solar cell subassembly 10 is separated (for example, cut) from the incoming roll of backplane material. The solar cell subassembly 10 can then be transferred to a module assembly or lay-up station where additional layers of encapsulant (for example, back sheet of encapsulant 52, FIG. 6B, and front sheet of encapsulant 16B, FIG. 7) can (optionally) be added to the top and/or back of the array assembly, a back cover 54 (optionally) can be added, and a front cover 62 (for example, glass) can be added. In one embodiment, a back cover 54 (for example, backskin) and layer of encapsulant (for example, back sheet of encapsulant 52) is laid down at a module assembly or lay-up station. Then the solar cell subassembly 10 is next placed at the station, then a further layer of encapsulant (for example, front sheet of encapsulant 16B), and then a front cover 62 (for example, glass) to create a layered construct or sandwich. The layered construct or sandwich is then subjected to thermal process, lamination process, and/or other assembly process to form the module (see FIG. 7).

If a front glass cover 62 has been provided previous to step 112, then a module has been formed that includes the solar cell subassembly 10. In this case, in step 114, the module is singulated for further processing, which can include adding a frame (of metal or other material) to support and protect the edges of the module and/or attachment of a junction box for electrical connections.

In another embodiment, the flexible electrical backplane 14 can be singulated at an earlier stage of the process, for example, before step 104, when the flexible electrical backplane 14 is separated (for example, cut) from a roll of backplane material used as input to the assembly station.

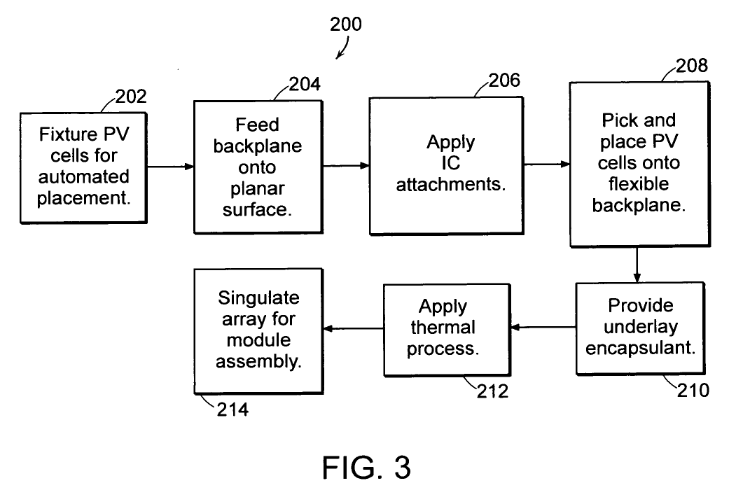

FIG. 3 is a flowchart of a module fabrication procedure 200 utilizing a flexible electrical backplane 14 and providing thermal processing, in accordance with the principles of the invention. In step 202, the PV cells 12 are fixtured or placed onto an automated pick and place robotic device to provide for an automated placement of the cells 12 onto the partially assembled module in a later step of the procedure 200 (see step 208). Then, in step 204, the procedure 200 feeds the flexible electrical backplane 14 onto a table or planar surface of an assembler device. For example, the flexible electrical backplane 14 is unrolled in an automated process onto the table from a roll of backplane 14 material attached to or available to the assembler device. In one embodiment, the backplane 14 material is automatically sized to a predetermined size (for a given size module), for example, the backplane 14 material is cut to the appropriate predetermined size. In another embodiment, the singulation of the module or partially assembled module occurs at step 214 of the procedure 200.

In one embodiment, three rolls of material are available to the assembler device. One roll is a back cover (for example, 54 in FIG. 6A), another roll is a back sheet of encapsulant (for example, 52 in FIG. 6A), and another roll is the backplane 14 material. These rolls are automatically and concurrently fed into the assembler so that the back cover 54 (for example, backskin), is the bottom layer, the back sheet of encapsulant is the next layer, and the backplane 14 material is the top layer. Then the three layers are sized to a predetermined size, in one embodiment. In one embodiment, one or more strips of encapsulant (for example, 56 in FIG. 6B) can be fed concurrently from a roll of material (see, for example, the discussion for FIG. 6B). In another embodiment, a back sheet of encapsulant (for example 52 in FIG. 6B) can include a protrusion or “rib” of encapsulant material (as described, for example, for FIG. 6B).

In one embodiment, the flexible electrical backplane 14 is fed or positioned onto the planar surface of the assembler device as sheets of backplane material. In another embodiment, the flexible electrical backplane 14 is fed from precut rolls of backplane material.

In step 206, the procedure 200 applies interconnect attachments 18 to predetermined portions of the conductive interconnects 18. In one embodiment, the process includes printing or providing a cover coat (or solder mask) 20 before applying an interconnect material that forms the interconnect attachments 18. The interconnect material, in various embodiments, can be a conductive adhesive or conductive ink. In other embodiments, the interconnect material is a metal particle material. In one embodiment, the process includes printing or providing a cover coat (or solder mask) 20 before applying the interconnect material. In one embodiment, the interconnect material is a solder or solder paste. The interconnect material is applied to form interconnect attachments 22 at predetermined positions that are located to align with the back contacts 26 of the PV cells 12, which occurs during step 208 when the PV cells 12 are placed onto the flexible electrical backplane 14.

In various embodiments, a syringe and needle approach is used to deposit or dispense the interconnect material to form the interconnect attachments 22. A pump or pressure approach is used to apply the interconnect material (for example, conductive adhesive) to the flexible electrical backplane 14.

In step 208, the procedure 200 places the PV cells 12 already fixtured in step 202 onto the flexible electrical backplane 14 so the back contacts on the PV cells 12 align with the interconnect attachments 22. In one embodiment, the placement of the PV cells 12 is performed by an automated pick and place device. In one embodiment, this device is an automated pick and place machine. In another embodiment, this device is a placement robot, for example a gantry robot or XY robot.

In step 210, an underlay encapsulant 16A is provided. In one embodiment, the underlay encapsulant 16A is one or more sheets of encapsulant material layered under the back surface 13 of the PV cells 12 and/or layered beneath the flexible backplane 14. In one embodiment, the flexible substrate 28 has windows (also termed “openings,” “cut-outs,” or “holes”) in parts of the flexible electrical backplane 14 that do not have conductive interconnects 18 embedded or included in the flexible electrical backplane 14. The windows allow for the encapsulant 16A to flow into spaces underneath the PV cells 12 when the thermal process is applied (step 212). In one embodiment, strips of encapsulant can be provided to insure that the spaces beneath the PV cells 12 are fully filled with encapsulant 16A (see FIGS. 6A and 6B).

In one embodiment, the underlay encapsulant 16A is a liquid encapsulant that is deposited or dispensed in gaps 38 between the PV cells 12, so that the liquid encapsulant flows into the spaces between the solar cells 12 and the flexible electrical backplane 14. In another embodiment, a liquid encapsulant is provided for the underlay encapsulant 16A before the placement of the photovoltaic cells 12 (that is, before step 208), and the liquid encapsulant is cured by the application of UV light. The interconnect attachments 22 can be covered with a mask material to prevent the interconnect attachments 22 from being covered with encapsulant 16A, and the mask material must be removed before the placement of the photovoltaic cells 12.

In step 212, the underlay encapsulant 16A is cured by applying a thermal process (for example, by infrared light), a microwave process, a UV light process, or other suitable curing process. The thermal or microwave process causes the encapsulant 16A to flow (if in the form of sheets and/or strips of encapsulant) material to fill the spaces underneath the PV cells 12 (that is, between the PV cells 12 and the conductive interconnects 18). In a substantially simultaneous process, the thermal or microwave process causers the PV cells 12 to bond to the flexible electrical backplane 14. In one embodiment, the thermal or microwave process causes a thermosetting conductive adhesive to set. In another embodiment, a UV light process causes the encapsulant 16A (for example, liquid encapsulant) to set. In another embodiment, a UV light process causes the conductive adhesive or conductive ink to set.

In another embodiment, the underlay encapsulant 16A is first treated with UV light to initiate a curing process (for example, for a liquid encapsulant 16), and then the curing is completed with a thermal process. In another embodiment, step 212 includes the application of pressure as well as other processes (for example, a thermal, microwave, and/or UV light process).

If a front cover (for example glass) 62 is placed over the PV cells 12 and a front encapsulant layer 16B provided between the front cover 62 and the PV cells 12, before step 212, then the front cover 62 can be bonded to the encapsulant 16B by the thermal process of step 212. In this approach, a solar module 60, as shown for example in FIG. 7, is produced.

In step 214, the procedure 100 singulates the solar cell subassembly 10 for module assembly. The solar cell subassembly 10 includes the flexible electrical backplane 14 attached (for example, soldered) to the PV cells 12, and the cured encapsulant 16A. In one embodiment, the solar cell subassembly 10 is separated (for example, cut) from the incoming roll of backplane material. The solar cell subassembly 10 can then be transferred to a module assembly or lay-up station where additional layers of encapsulant (for example, back sheet of encapsulant 52, FIG. 6B, and front sheet of encapsulant 16B, FIG. 7) can (optionally) be added to the top and/or back of the array assembly, a back cover 54 (optionally) can be added, and a front cover 62 (for example, glass) can be added. In one embodiment, a back cover 54 (for example, backskin) and layer of encapsulant (for example, back sheet of encapsulant 52) is laid down at a module assembly or lay-up station. Then the solar cell subassembly 10 is next placed at the station, then a further layer of encapsulant (for example, front sheet of encapsulant 16B), and then a front cover 62 (for example, glass) to create a layered construct or sandwich. The layered construct or sandwich is then subjected to thermal process, lamination process, and/or other assembly process to form the module (see FIG. 7).

If a front glass cover 62 has been provided previous to step 212, then a module has been formed that includes the solar cell subassembly 10. In this case, in step 14, the module is singulated for further processing, which can include adding a frame (of metal or other material) to support and protect the edges of the module and/or attachment of a junction box for electrical connections.

In another embodiment, the flexible electrical backplane 14 can be singulated at an earlier stage of the process, for example, before step 206, when the flexible electrical backplane 14 is separated (for example, cut) from a roll of backplane material used as input to the assembly station.

The procedures 100 described in FIGS. 2 and 200 described in FIG. 3 can be, in one embodiment, a discrete panel process, in which discrete solar cell subassemblies 10 or solar modules are produced. In various embodiments, the procedures 100 and 200 can be adapted to a continuous flow manufacturing approach in which backplane material is input from a roll in a continuous manner, and solar cell subassemblies 10 (or complete solar cell modules) are separated at the end of a continuous processing line.

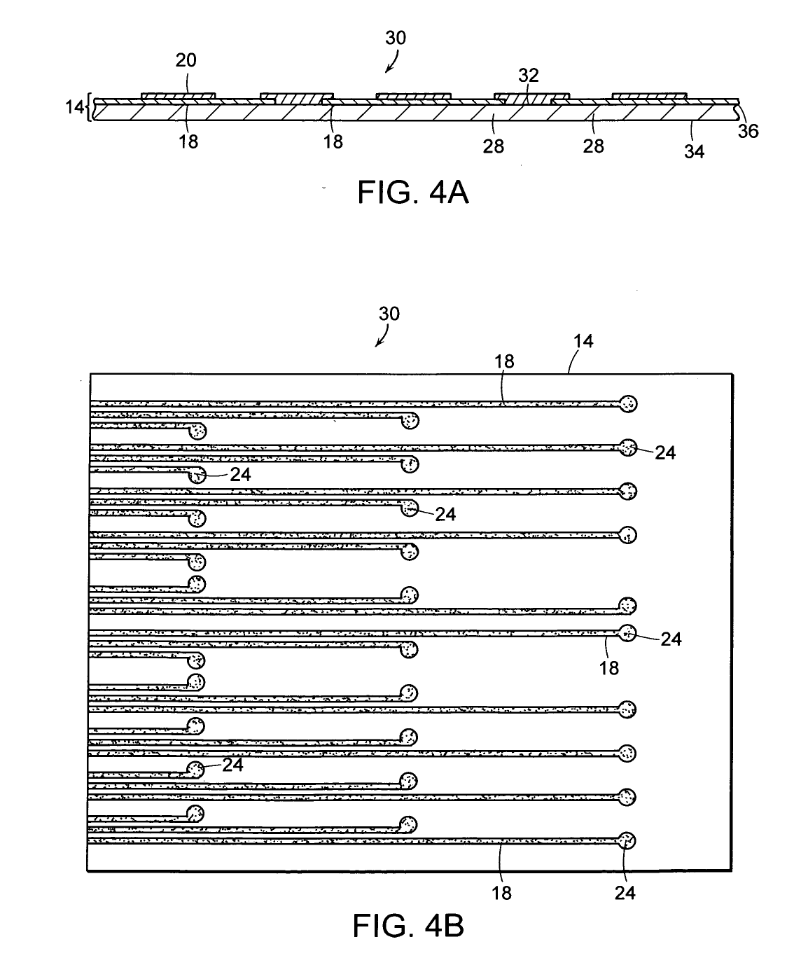

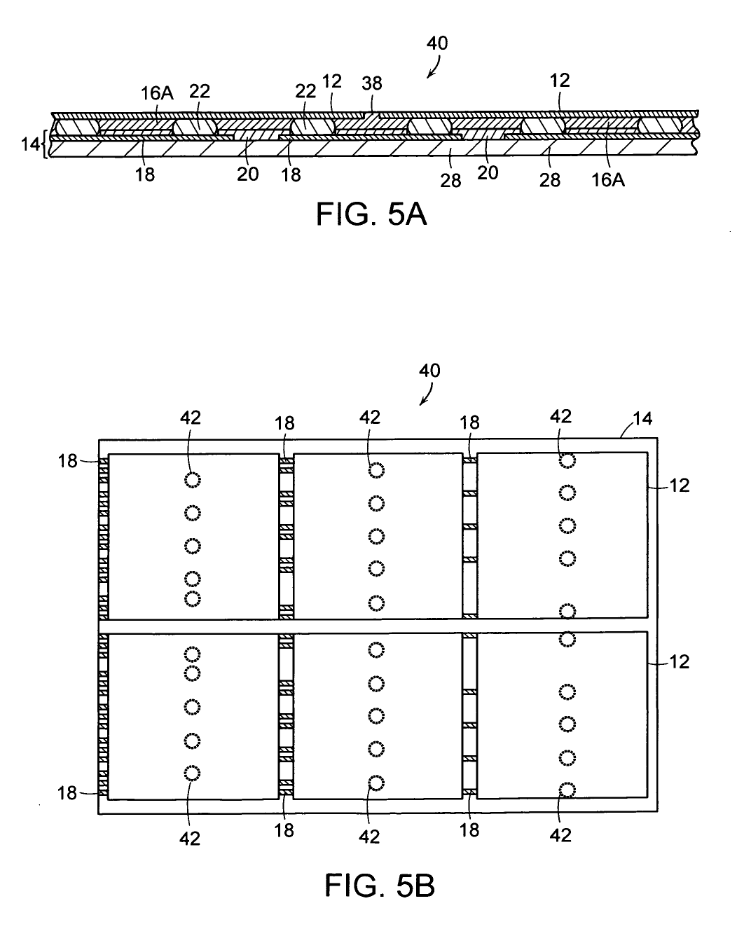

FIGS. 4A and 4B show a schematic view of the flex-based backplane interconnect system 30 of the invention used in a different configuration than shown in FIG. 1; and FIGS. 5A and 5B show the solar cell subassembly 40 applied to an EWT cell design with a central row of contacts 42 on the back surface of the EWT photocell 12.

FIG. 4A is a side view of a flex-based interconnect system 30 in accordance with the principles of the invention. In the embodiment shown in FIG. 4A, the flex-based interconnect system 30 includes the flexible electrical backplane 14, and the cover coat (or solder mask) 20. FIG. 4A thus illustrates the basic flex-based interconnect system 30, to which interconnect attachments (or tabs) 22 can be attached to the exposed conductive interconnect 18 material (also referred to as interconnect pads 24, see FIG. 4B). The flexible electric backplane 14 includes conductive interconnects 18, and a flexible substrate 28.

FIG. 4B is a plan view of the flex-based interconnect system 30 of FIG. 4A. The plan or overhead view shown in FIG. 4B illustrates one embodiment of the conductive interconnects 18, which connect to interconnect pads (designated generally by the reference numeral 24). The approach of the invention is not limited to the pattern or configuration of conductive interconnects 18 and interconnect pads 24 shown in FIG. 4B. In one embodiment, other patterns of conductive interconnects 18 and interconnect pads 24 can be used, for example, to provide for openings or windows (for example, 50 in FIG. 6A) in the flexible substrate 28 beneath each PV cell 12, as discussed elsewhere herein. In one embodiment, the conductive interconnects 18 are covered with the cover coat (or solder mask) 20 (not shown in FIG. 4B), and the interconnect pads 24 remain exposed so that interconnect attachments (or tabs) 22 can be placed on the interconnect pads 24. In one embodiment, the interconnect attachments 22 include an interconnect material of solder paste that is printed (or otherwise) applied to the interconnect pads 24 to form solder paste interconnect attachments 22. In one embodiment, the solder is plated onto the flexible electrical backplane 14 in an electroplating process, and etched back to produce the predetermined pattern, if required. In one embodiment, the solder is pattern plated onto the flexible electrical backplane 14, so that an etch back is not required. The conductive interconnects 18 extend to the left beyond the view shown in FIG. 4B to connect with electrical circuitry that provides connections to circuits that collect the electrical current for the module and to an electrical junction box for the module; and further connect to electrical connections outside of the module that collect the current, typically, for an array of modules (not shown in FIG. 4B).

In the approach of the invention, key materials include the following: backplane flex circuit material for the flexible electrical backplane 14; metallization of the backplane interconnects 18; metallization of the PV cell 12; PV cell 12 to backplane 14 interconnect material for the interconnect attachments 22; and PV cell 12 to backplane 14 underlay material for stress relief and void elimination beneath the PV cell 12.

The backplane flex circuit material for the flexible electrical backplane 14 is based on a flexible substrate 28 of various materials in various embodiments of the invention. In one embodiment, the flexible backplane material used in the flexible substrate 28 is a flexible polymer material. In another embodiment, the flexible backplane material is a polyimide material. In another embodiment, the flexible backplane material is an LCP (liquid crystal polymer). The flexible backplane material, in various embodiments, is a polyester, or can be a polyolefin, such as polyethylene or polypropylene. In other embodiments, the flexible backplane material is a cloth or cloth-like material that can be woven or nonwoven. In another embodiment, the flexible backplane material can be a paper or paper-like product or material, for example, a high temperature bonded paper that is ionically pure. The flexible backplane material can also be based on suitable materials to be developed in the future.

In one embodiment, the flexible electrical backplane 14 becomes part of the encapsulant material 16 if the flexible electrical backplane 14 includes an encapsulant material, such as EVA. In such a case, a back sheet of encapsulant (for example, 52 in FIG. 6B) adjacent to the back surface 34 of the flexible electrical backplane 14 is not required, and a back cover (for example 54 in FIG. 6B), such as glass or a backskin, is optionally provided adjacent to a back surface 34 of the flexible electrical backplane 14 to provide a protective back cover.

In one embodiment, the flexible substrate 28 of the flexible electrical backplane 14 is a removable substrate that can be removed, for example, by being dissolved by water or a solvent, while retaining the conductive interconnects 18 and interconnect pads 24. In one embodiment, after removal, a layer of encapsulant (for example, back sheet of encapsulant 52) and a back cover (for example, 54), such as glass or a backskin, is optionally provided. The back sheet of encapsulant 52 is provided adjacent to or bonded to a back surface 36 (facing away from the PV cells 12) of the conductive interconnects 18 and interconnect pads 24 and then a back cover 54 is provided adjacent to or bonded to a back surface 58 (facing away from the PV cells 12) of the back sheet of encapsulant 52 to provide a protective back cover. In another embodiment, after removal, a back cover 54 (for example, glass or a backskin) is provided adjacent to or bonded to a back surface 36 (facing away from the PV cells 12) of the conductive interconnects 18 to provide a protective back cover.

In another embodiment, the flexible substrate 28 has windows, openings cut-outs, or holes in parts of the flexible electrical backplane 14 that do not have conductive interconnects 18 embedded or included in the flexible electrical backplane 14. In one embodiment, the flexible electrical backplane 14 is placed next to a sheet of encapsulant (for example, 52) adjacent to the bottom or back surface 34 of the flexible electrical backplane 14. In one embodiment, the windows located adjacent to the back surface 13 of the PV cells 12 allow encapsulant 16A to flow into the spaces beneath the PV cells to insure that these spaces are filled with encapsulant; for example, when subjected to heat in a thermal process, or to both heat and pressure as part of a lamination process for a solar electric module. In another embodiment, strips of encapsulant (for example, 56) are provided that approximately fill each window (see FIGS. 6A and 6B). When the encapsulant is heated, the strips of encapsulant 56 flow into the spaces beneath the PV cells to insure that these spaces are filled with encapsulant. In another embodiment, the windows enable a liquid encapsulant 16 to flow into the spaces underneath the PV cells 12.

The metallization of the backplane interconnects 18 can be based on a conductive metal such as copper, aluminum, silver, gold, or related alloys. In one embodiment, the conductive interconnects 18 is based on copper with an antioxide surface coating, which can be an organic surface coating. In another embodiment, the conductive interconnects 18 are copper plated with silver or gold. In another embodiment, the conductive interconnects 18 are composed of a material that is not solder wettable, such as nickel, or a metal (for example, copper) plated with nickel, and a cover coat 20 is not required. The interconnect pads 24 are composed of a solder wettable material (for example, copper).

In another embodiment, the backplane interconnects 18 are composed of a conductive adhesive or a conductive ink; for example, when the flexible backplane is composed of a polyester material with conductive ink applied or printed onto the polyester material to form the backplane interconnects 18. The conductive interconnects 18 can also be based on suitable materials to be developed in the future.

The metallization of the PV cell 12 requires that the contacts (for example, back contacts 26) be solder wettable, or, if not, then the contacts are compatible with conductive adhesives or conductive inks. The metallization of the PV cell (for example, back contacts 26 and electrical circuitry used to collect current such as fingers and busbars) can be based on a conductive metal such as copper, aluminum, silver, gold, or related alloys. In one embodiment, the back contacts 26 are based on copper with an antioxide surface coating, which can be an organic surface coating.

The interconnect material used in the interconnect attachments 22 is solder in one embodiment. In one embodiment, the solder is a lead free SAC alloy (tin, silver, and copper alloy). The solder can include a flux, in which case a flux residue can remain after the soldering process. In another embodiment, a wash cycle can be performed after the soldering process to remove the flux, before other steps such as adding encapsulant 16. The solder can also be a fluxless solder. In one embodiment, the soldering process is done in a vacuum with fluxless solder. In one embodiment, the solder is a low temperature solder, useable at a temperature as low as 80 degrees centigrade; for example, an indium based solder. In another embodiment, the interconnect material is a conductive adhesive. In other embodiments, the interconnect material is a metal particle material. In one embodiment, the manufacturing process is related to those used in the semiconductor printed-board industry; for example, the interconnect material is a conductive adhesive with a compression bond process using metal bumps with gold-coated surfaces designed to promote adhesion under a compression force introduced during a process involving pressure, such as a lamination process; for example forming a bond between the conductive interconnects 18 and the contacts 26. In one embodiment, the compression bond process is done without any interconnect material to form a bond between the conductive interconnects 18 and the contacts 26. The interconnect attachments 22 can also be based on suitable materials, such as new types of solder, to be developed in the future.

The underlay encapsulant 16A is, in one embodiment, a liquid encapsulant, for example, a liquid form of a polymer based material, such as EVA, and/or an epoxy material. In other embodiments, the liquid encapsulant is a plastic material, such as an acrylic or urethane material, a silicone rubber material, or other transparent suitable material. In one embodiment, the encapsulant is a high temperature encapsulant, suitable for use with a fluxless solder process and/or low temperature solder. In another embodiment, the encapsulant 16A is a film encapsulant or a sheet of encapsulant (for example, a film or sheet of a polymer based material). The film or sheet of encapsulant 16A, in one embodiment, has a punched pattern that matches the PV cell 12 pattern. The interconnect attachments 22 can also be based on suitable encapsulating materials to be developed in the future.

If a backskin is included (for example, for a back cover 54), the backskin can be a TPT backskin. TPT is a layered material of TEDLAR®, polyester, and TEDLAR®. TEDLAR® is the trade name for a polyvinyl fluoride polymer made by E.I. Dupont de Nemeurs Co. In one embodiment, the TPT backskin has a thickness in the range of about 0.006 inch to about 0.010 inch. In another embodiment, the backskin is composed of TPE, which is a layered material of TEDLAR®, polyester, and EVA, or thermoplastic EVA. In one embodiment, the backskin is PROTEKT® HD available from Madico, Woburn, Mass.

FIG. 5A is a side view of a solar cell subassembly 40 including a flex-based interconnect system suitable for use with an emitter wrap-through (EWT) application, according to the principles of the invention.

The solar cell subassembly 10 includes photovoltaic cells 12, a flexible electric backplane 14, encapsulant 16A, cover coat 20, and interconnect attachments 22 of interconnect material. The flexible electric backplane 14 includes conductive interconnects 18, and a flexible substrate 28. The approach of the invention does not require the spacing of interconnect attachments 22 to be evenly spaced. The PV cells 12 can also include conductive contacts 26; for example, backside contacts (not shown in FIG. 5A). The positioning of the interconnect attachments 22 is predetermined to align with the conductive contacts 26 (not shown in FIG. 5A) so as to form a conductive path between each PV cell 12 and the conductive interconnects 18.

The solar cell subassembly 40, in one embodiment, can be used with other layers, such as a front or top layer of encapsulant 16B or the front cover 62 of glass or other transparent material, or back layers, such as a back sheet of encapsulant (for example, 52) and back cover (for example, 56). In one embodiment, the encapsulant 16B and front cover 62 are layered with the solar cell subassembly 10, optionally with other layers of materials (for example, 52 and/or 56), and subjected to a lamination process, thermal process, or other manufacturing process to form a solar electric module (see FIG. 7).

FIG. 5B is a plan view of the solar cell subassembly 40 of FIG. 5A, including PV cells 12, conductive interconnects 18, central contacts 42 (designated generally by the reference numeral 42) on the back side of the PV cell 12, and vias (not shown in FIG. 5B). The vias are holes in the PV cell 12 providing an electrically conductive path from the front surface 11 of the PV cell 12 to the back surface 13 of the PV cell 12, as described elsewhere herein. The vias connect to collector electrodes (not shown in FIG. 5B) on the front of the PV cell 12. In one embodiment, the vias are filled with metal to provide the conductive path to the back surface 13 of the PV cell 12. In one embodiment, the vias are aligned with the central contacts 42, which in turn align with the interconnect attachments 18. In another embodiment, the vias do not align with the central contacts 42, and connect to backside circuitry located on the back surface 13 of the PV cell 12, which in turn connects to the central contacts 42. FIG. 5B is not meant to be limiting of the approach of the invention; for example, the contacts 42 can have positions other than those shown.

FIGS. 6A and 6B are exploded side views of a partial solar module illustrating a window 50 in a flexible substrate 28 of the flexible electrical backplane 14. The partial solar module of FIG. 6A includes a back cover 54, an encapsulant back sheet 52, flexible substrate 28, conductive interconnects 18, interconnect attachments 22, and PV cell 12 with conductive contacts 26. In one embodiment, the flexible substrate 28 and conductive interconnects 18 form the flexible electrical backplane 14. In one embodiment, the conductive contacts 26 form two parallel rows or strips of contacts located on the back surface 13 of the PV cell 12 near or close to two opposing edges of the PV cell 12.

The flexible substrate 28 has a window 50 that is disposed underneath the PV cell 12. The window 50 allows the encapsulant back sheet 52 to flow into the opening provided by the window 50 to fill the space below the PV cell 12 (and bounded generally on the edges by the contacts 26 and interconnect attachments 22, as shown in FIG. 6A). If a liquid encapsulant 16A is used alone or in combination with a back sheet of encapsulant 52, then the liquid encapsulant 16A fills the space provided by the window 50. The window 50 allows UV light to be incident on the liquid encapsulant 16A, because the typically opaque flexible substrate 28 has been removed in the area of the window 50, and the back cover 54 is either transparent to UV light, or the back cover 54 has not yet been provided.

The window 50, in one embodiment, is about 80 percent through about 90 percent of the size of the PV cell 12 (that is, the bottom surface 13 of the PV cell 12). FIGS. 6A and 6B are not meant to be limiting of the number of windows 50 provided for each PV cell 12.

In FIG. 6B, opening of the window 50 is partially or substantially filled by a strip of encapsulant 56. The strip of encapsulant 56 is not limited by the invention to be a strip of rectangular shape or any particular geometric shape, just as the shape of the window 50 and the number of windows 50 are not limited by the invention. The strip of encapsulant 56, in various embodiments, can be two or more sheets of encapsulating material (which can have different shapes and sizes) and can be different types of encapsulant (for example, ionomer and/or polymer encapsulants). The strip of encapsulant 56 is not required by the invention to be the same encapsulating material as other encapsulant material 16 or as the back sheet of encapsulant 52. The back sheet of encapsulant 52 can be optional, in one embodiment, if a strip of encapsulant 56 is used. The strip of encapsulant 56 is provided to supply an ample or even extra supply of encapsulating material to insure that the space underneath the PV cell 12 is filled by encapsulant 56, because the encapsulant (for example, 52 and 56) can shrink during the curing and/or thermal process.

In another embodiment, the strip of encapsulant 56 is combined with the back sheet of encapsulant 52, forming a protrusion or “rib” on the back sheet 52. The rib is not required by the invention to have the shape indicated by FIG. 6B, but can have various shapes, such as curved (for example, a semicircle, an arc, or “hill” type of shape), pyramidal, trapezoidal, frustum based, or other type of shape, that can protrude into the opening provided by the window 50.

In another embodiment, liquid encapsulant 16 can also be provided, for example deposited or dispensed in gaps 38 between photovoltaic cells 12, to flow into contact with the outermost edges of the conductive contacts 26, the interconnect attachments 22, and the conductive interconnects 18 (the edge areas farthest away from the window 50) to insure their coverage with encapsulant 16 and to insure that the gaps 38 between photovoltaic cells 12 are filled with encapsulant.

The position of the contacts 26 and window 50 shown in FIGS. 6A and 6B is not meant to be limiting of the invention. In various embodiments, the contacts 26 are in various positions and the window 50 is sized accordingly, and more than one window 50 can be used for each PV cell 12. In one embodiment, the contacts 26 form three parallel rows or strips on the back side of each PV cell 12, and two windows 50 are provided that allow for two strips of encapsulant 56, each window 50 located between two of the parallel rows or strips of contacts 26. For example, three parallel strips of contacts 26 can be used when the PV cell 12 is relatively large, for example, about 20 centimeters by about 20 centimeters.

FIG. 7 is a side view of a solar electric module 60 including the flex-based interconnect system, in accordance with the principles of the invention. The solar electric module 60 includes photovoltaic cells 12, a flexible electric backplane 14, encapsulant 16, cover coat 20, interconnect attachments 22 of interconnect material, a front cover 62 of a transparent material (for example, glass, transparent polymer, or other transparent material) and a back cover 54 (for example, backskin). The flexible electric backplane 14 includes conductive interconnects 18, and a flexible substrate 28. As shown in FIG. 7 the encapsulant 16 includes a layer of underlay encapsulant 16A beneath the PV cells 12, and a front or top layer of encapsulant 16B located between the PV cells 12 and the front cover 62. Where an array of PV cells 12 have gaps 38 (that is, longitudinal openings or slots) between the PV cells 12, the front layer of encapsulant 16B and the underlay encapsulant 16A are in contact, and during a thermal or other curing process, the two layers, 16A and 16B, merge at the gaps 38. The solar electric module 60 can also include conductive contacts 26 located on the back side of the PV cells 12 (not shown in FIG. 7).

In one embodiment, the solar electric module 60 is formed by placing a solar cell subassembly (for example, 40) on a back cover 54 disposed on a planar surface in an assembler or laminating device, next placing a front layer of encapsulant 16B (for example, sheet of encapsulant) having a front surface 64 facing away from the photovoltaic cells 12, and then next placing a front cover 62 adjacent to the front surface 64 of the front layer of encapsulant 16B, and then subjecting these components (for example, back cover 54, subassembly 40, encapsulant 16B, and 62 front cover) to a thermal or lamination process (that involves heat and pressure applied substantially simultaneously). In one embodiment, a protective back coating is applied to the back surface 34 of the flexible electrical backplane 14.

In another embodiment, a solar electric module is formed by placing a back cover 54 (for example, backskin) on a planar surface in an assembler or a laminating device, next a sheet or layer of encapsulant 52, next a solar cell subassembly (for example, 40), next placing a front layer of encapsulant 16B (for example, sheet of encapsulant), and then next placing a front cover 62. These components (for example, back cover 54, encapsulant 52, subassembly 40, encapsulant 16B, and front cover 62) are then subjected to a thermal process or lamination process that involves heat and pressure applied substantially simultaneously to form a solar electric module 60. In a further embodiment, the substrate 28 of the flexible electrical backplane 14 of the solar cell subassembly (for example 40) is removed before placing the solar cell subassembly (for example 40) into the assembly or lamination device. The solar cell subassembly (for example, 40) retains the conductive interconnects 18 after removal of the substrate.

In one embodiment, the solar electric module 60 of FIG. 7 can include a flexible substrate 28 having windows 50, and the space indicated by the windows 50 would be filled by encapsulant 16A. In one embodiment, if windows 50 are used, then a back sheet of encapsulant is included in the solar electric module 60 between the flexible substrate 28 and the back cover 54 (for example, backskin), as well as optionally including one or more strips of encapsulant 56. In another embodiment, if windows 50 are used, the cover coat 20 is not used.

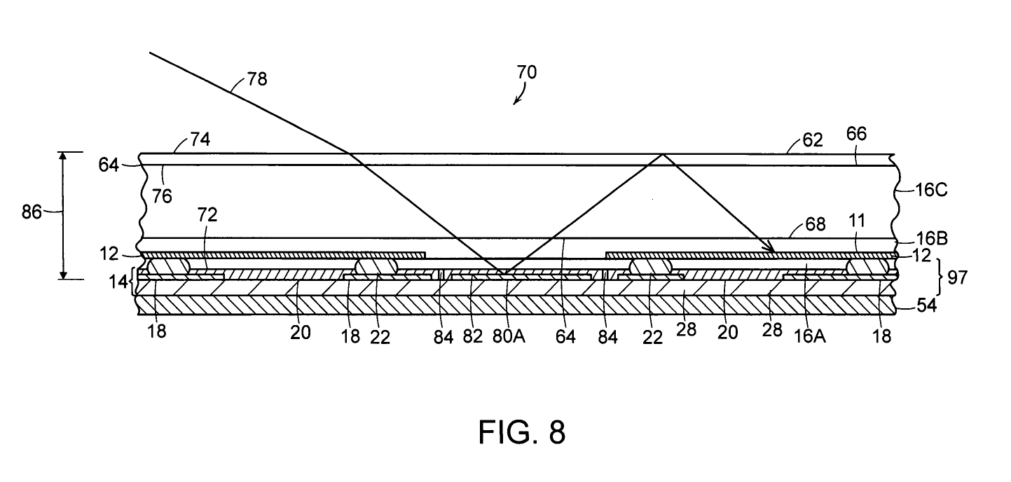

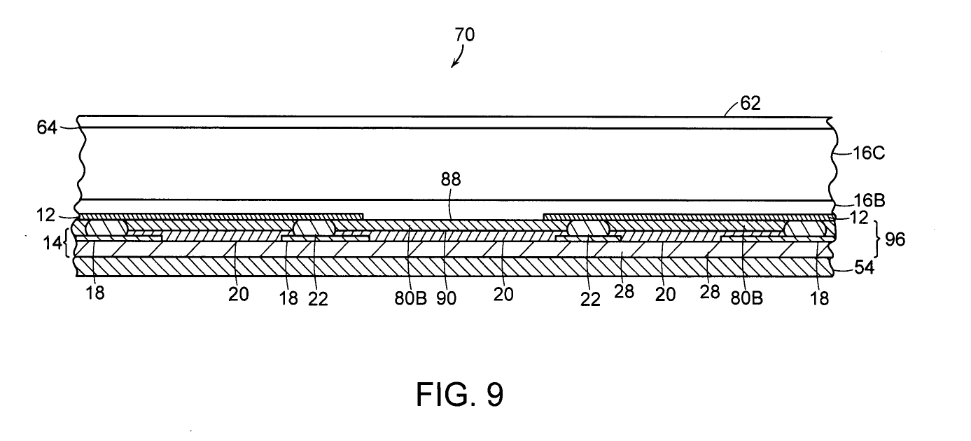

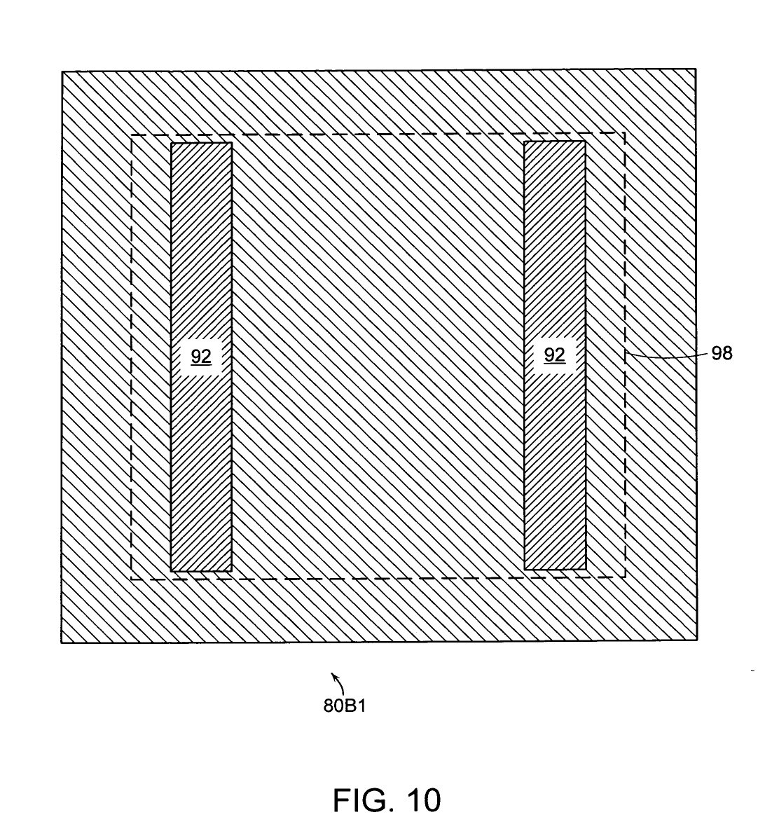

FIG. 8 is a side view of a light concentrating module 70 with an integrated light concentrating layer 80A (integrated light concentrating layer 80A, and patterned light concentrating layer 80B (see FIG. 9) are referred to generally as “light concentrating layer 80”), in accordance with the principles of the invention. The light concentrating module 70 of FIG. 8 includes a front cover 62 (for example, glass) having a front surface 74 and back surface 76. The light concentrating module 70 includes a light transmitting encapsulant 16 (referring generally to underlay encapsulant layer 16A, front encapsulant sheet or layer 16B, and additional encapsulant layer 16C). The additional encapsulant layer 16C has a front surface 66 and back surface 68. In one embodiment, the term “overlay encapsulant” includes both the front encapsulant layer 16B and additional encapsulant layer 16C. In various embodiments, the encapsulant layers 16A, 16B, and 16C are not required to be composed of the same encapsulating materials, and different layers 16A, 16B, and 16C can be composed of different encapsulating materials. For example, the encapsulating layers 16B and 16C can be composed of silicone or polyurethane materials.

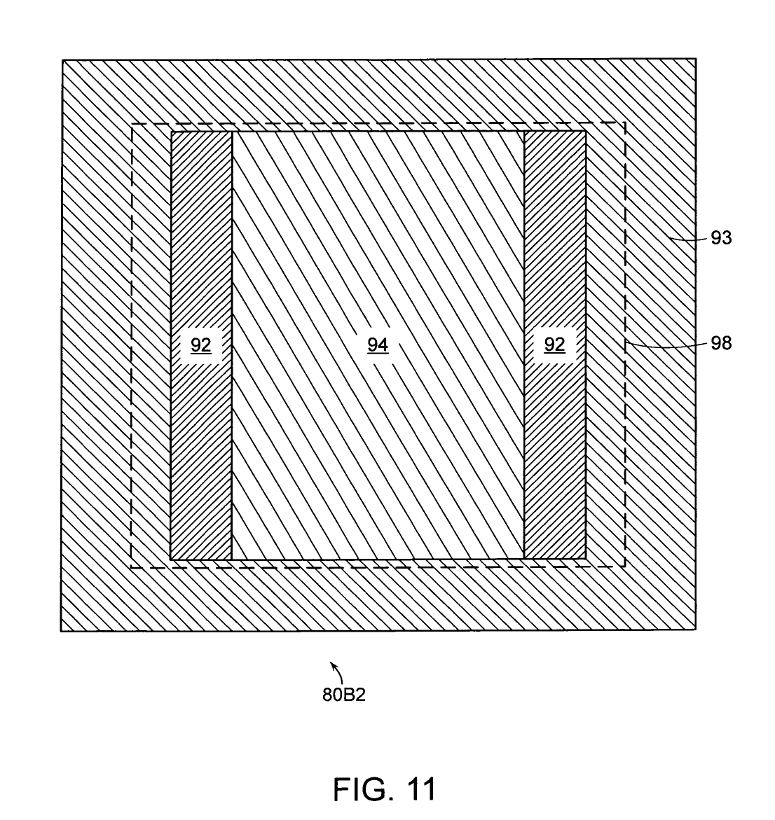

The flexible electric backplane 14 includes the integrated light concentrating layer 80A, which has a front or top surface 82. The integrated light concentrating layer 80A is separated from the conductive interconnects 18 by intervals 84 between the integrated light concentrating layer 80A and the conductive interconnects 18, so that the intervals 84 substantially eliminate electrical communication between the integrated light concentrating layer 80A and the conductive interconnects 18. In one embodiment, the conductive interconnects 18 and/or light concentrating layer 80A is coated with an insulating material (not shown in FIG. 8) to prevent leakage of electric current. The back cover or backskin 54 is an optional cover or layer, in one embodiment, and is not included if the flexible electrical backplane 14 is capable of serving as the back cover or backskin and does not require a separate back cover or backskin 54. The interconnect attachments 22 provide electrical connections between the conductive interconnects 18 and the back contacts of the solar cells 12. The conductive interconnects 18 and any interconnect pads 24 (not shown in FIG. 8) associated with them are configured and are exposed in a pattern that corresponds to the back contacts of the solar cells 12, and the description and figures herein are not intended to be limiting of the shapes and patterns of exposed areas of conductive interconnects 18 and corresponding interconnect attachments 22 and interconnect pads 24. For example, the exposed areas can form longitudinal or rectangular shapes, as indicated by the apertures 92 shown in FIGS. 10 and 11, which correspond to the shape of the back contacts of one embodiment of the solar cells 12.

Elements and techniques for module construction are described herein which enable simpler manufacturing procedures. These elements and techniques can be combined with concentrating light principles in designs for light concentrating solar modules 70 which use light redirecting materials to reduce module costs by reducing the number of solar cells 12 used to as few as one-half of those used in conventional modules without a light concentrating feature that redirects light rays 78 to concentrate the light rays 78 on the front surfaces 11 of solar cells 12.

The light concentrating solar module 70 combines the advantages of the back contact solar cell 12 and a light concentrating approach. The back contact solar cell 12 provides the advantage of higher performance, because metallization (for example, bus bars) are not required on the front surfaces 11 of the solar cell 12. In a light concentrating approach, the solar cells 12 are spaced apart, and cost reductions are realized by enabling the total number of cells in a module 70 to be reduced while maintaining module performance (that is, maintaining a substantially similar level of output of electrical power as modules without a light concentrating approach).

Thus, the embodiments of the invention provide the benefits of increasing performance for each solar cell 12 by using the back contact approach to provide a larger area on the front of the solar cell 12 that is available to receive light rays 78 because of less light obstructive metallization on the front of the solar cells 12, while using a light concentrating approach to increase the amount of light (including redirected light rays 78) that is redirected or concentrated to the front surface 64 of each solar cell 12.

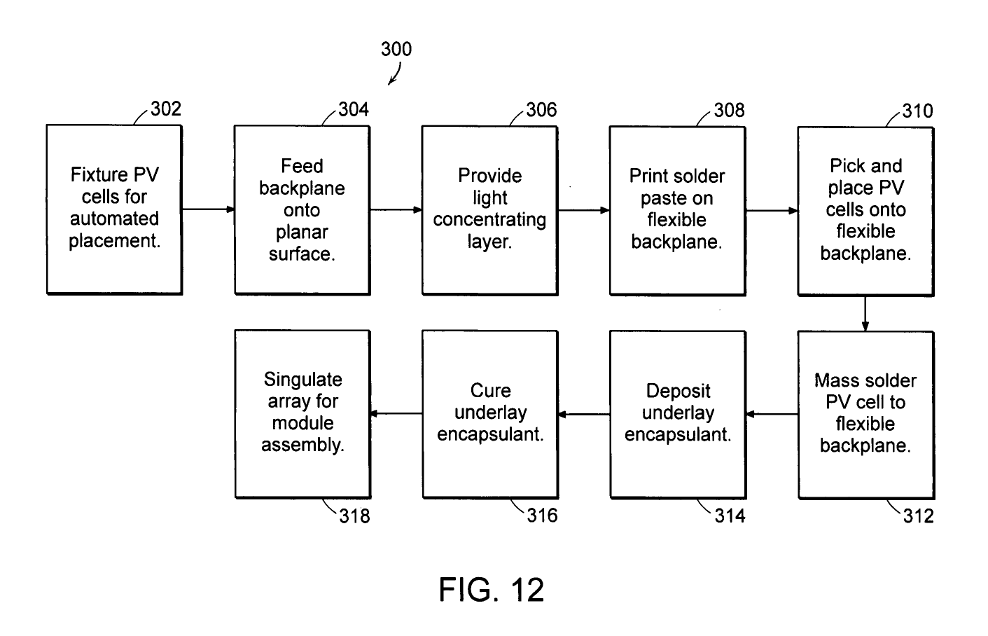

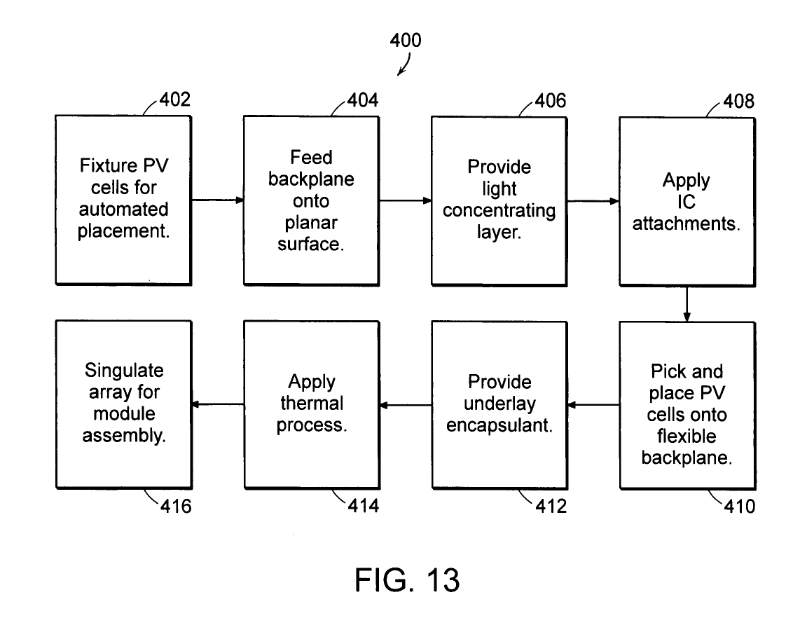

Embodiments of the invention provide for reduced steps in manufacturing the light concentrating module 70 by including the light concentrating layer 80 as an integral part of the flexible electrical backplane 14 (integrated light concentrating layer 80A) or providing the light concentrating layer 80 as a separate patterned light concentrating layer 80B. In one embodiment, the patterned light concentrating layer 80B can be preassembled with the flexible electrical backplane 14 before beginning the manufacturing process (see FIGS. 12 and 13 the associated discussion elsewhere herein). In a further embodiment, the patterned light concentrating layer 80A can be provided from a roll of material to feed onto a planar surface concurrently with the flexible electrical backplane 14.

Referring now to FIG. 8, light ray (such as a solar ray) 78 is incident upon the light concentrating module 70, and enters the module 70 through the front surface 74 of the front cover 62. The paths and angles of the light ray 78 as shown in FIG. 8 are not meant to be limiting of the invention, and light rays 78 are incident from various positions, and form various angles with the front surface 74 of the front cover 62 when a light ray 78 is incident on the front surface 74. In the example shown in FIG. 8, the light ray 78 is subject to refraction at the front surface 74 of the front cover 62, as the light ray 78 passes from a less dense medium (typically, the air outside of the light concentrating solar module 70) into a more dense medium (of the front cover 62). In one embodiment, the front cover 62 has about the same index of refraction as the light transmitting encapsulant 16, so that, in the example shown in FIG. 8, the light ray 78 is bent (downward or toward the normal) by refraction at the front surface 74, but no further substantial bending occurs as the light ray 78 passes through the back surface 76 of the front cover 62 into the light transmitting encapsulant layer 16C. In other embodiments, the front cover 62 and light transmitting encapsulant layer 16C can have different indexes of refraction, as long as the path of the light ray 78 is not generally changed as it moves downward and retains a path toward the integrated light concentrating layer 80.

The light ray 78 passes through encapsulant layers 16C, 16B, 16A, and the cover mask 20 and is incident on the integrated light concentrating layer 80A. The cover mask or coat 20 is a transparent layer that allows for the passage of the light ray 78 from encapsulant layer 16A through the cover mask 20 to the front surface 82 of the integrated light concentrating layer 80A. The cover mask 20 serves to mask the conductive interconnects layer 18, except for exposed areas for the interconnect attachments 22 where no mask 20 is provided. In various embodiments, the cover mask 20 is not required when the interconnect attachments 22 do not require a cover mask 20, such as for a conductive adhesive or ink, or the conductive interconnects 18 are a material that is not solder wettable, such as nickel or a conductive metallic material plated with nickel. If a nickel coating or plating is used, then the nickel coating or plating is not applied in exposed areas where interconnect attachments 22 of solder are expected to be provided. If the cover mask 20 is not included, then the light ray 78 is incident on the front surface 82 of the integrated light concentrating layer 80A after passing through the encapsulant layers 16C, 16B, and 16A.

After striking the integrated light concentrating layer 80A, the light ray 78 is redirected toward the front cover 62 as shown in the example provided in FIG. 8. The light ray 78 is incident on the front cover 62 if the light ray 78 does not strike an intervening object, such as a solar cell 12. If the light ray 78 forms an appropriate angle with the front surface 74 of the front cover 62, then the light ray 78 is reflected by total internal reflection toward the solar cells 12. If the light ray 78 is reflected, but does not strike the front surface 11 of a solar cell 12, then the light ray 78 can strike the integrated light concentrating layer 80A and be redirected again toward the front cover 62.

The integrated light concentrating layer 80A is a layer included integrally in the flexible electrical backplane 14. In various embodiments, the light concentrating layer 80 is composed of a reflective material, such as aluminum, silver, chromium, or other reflective material, or is a metallic material coated with a reflective metallic material, such as nickel. In the manufacturing of the flexible electrical backplane 14, in one embodiment, the conductive interconnects 18 and the integrated light concentrating layer 80A are composed of the same reflective metallic material.

In one embodiment, the integrated light concentrating layer 80A is composed of a metallic material coated with nickel, which allows the light concentrating layer 80A and conductive interconnects 18 to be composed of the same material and manufactured in the same step when forming the flexible electrical backplane 14; for example, an etching step that etches a metallic layer (composed of nickel or plated or coated with nickel) in a selective manner to reveal the patterns of conductive interconnects 18 and light concentrating layer 80A. Thus the use of such an integrated light concentrating layer 80A (a metallic material coated with nickel) provides the unexpected and fruitful results of adding functionality (the light redirecting layer 80A) without adding a new step to the manufacturing of the flexible electrical backplane 14, while eliminating a cover mask 20 that is not required in a soldering process when nickel or a nickel coating on the conductive interconnects 18 is used (because the nickel is not solder wettable).

In another embodiment, the conductive interconnects 18 and the integrated directing layer 80A are composed of an epoxy or transparent polymeric material including electrically conducting particles (for example, metallic particles) that also provide light diffusion, light scattering, and/or light redirection that is capable of directing a light ray 78 away from the integrated light concentrating layer 80A and toward the front cover 62, resulting in the concentration of light rays 78 on the front surfaces 11 of the solar cells 12. In other embodiments, the conductive interconnects 18 and the integrated light concentrating layer 80A are composed of different materials.

In various embodiments, the integrated light concentrating layer 80 (for example, 80A and 80B) is based on a reflective metallic material, as well as other materials. One such material, in one embodiment, is a grooved material that can be plated or coated with a metallic material that provide light reflecting properties, or based on other geometric shapes, such as pyramids, that can be coated or plated with a metallic material.

In various embodiments, the light concentrating layers 80 include a light reflective material, such as one that is white or lightly colored that reflects most of the light incident on the light concentrating layer 80 so that light rays 78 are concentrated on the front surfaces 11 of solar cells 12.

In another embodiment, the light concentrating layer 80 is based on a material that is a diffractive material that diffracts light rays 78 that strike the light concentrating layer 80 so that the light rays 78 are concentrated on the front surfaces 11 of solar cells 12. In one example, the diffractive material is based on appropriately sized grooves. In another embodiment, the diffractive material is a blazed diffractive material. In a further embodiment, the diffractive material is based on a computer generated diffractive optical (CGDO) material, kinoform, or computer generated holographic material.

In another embodiment, the light redirecting layer 80 is based on a material that is a light scattering material, such as a polymeric material or epoxy material including light directing particles of pigments, mica, spheres, metallic particles, and/or other particles, or including bubbles capable of redirecting light so that the light rays 78 are concentrated on the front surfaces 11 of solar cells 12.

Published patent application number WO2008/097517 by Juris P. Kalejs, Michael J. Kardauskas, and Bernhard P. Piwczyk describes light scattering layers, light diffraction layers, and other reflective layers suitable for use with the invention.

In one embodiment, the intervals 84 between the conductive interconnects 18 and the light concentrating layer 80 (having a metallic component) serve a moisture control function to provide controlled moisture ingress to and egress from the module interior.

Moisture control features suitable for use with the invention are discussed in U.S. Published Patent Application 2008/0185033 by Juris P. Kalejs, the contents of which are incorporated by reference.

Generally, the light concentrating solar module 70 can include moisture permeability areas that allow for the transport of moisture into and out of the module 70, according to the principles of the invention, which can be useful when metallic coatings or layers are included (such as in the light concentrating layer 80) that block the movement of moisture through the metallic layer. The moisture permeability areas can include areas underneath the solar cells 12 where metallic conductive interconnects 18 do not extend. In one embodiment, the moisture permeability areas are spaces (also referred to as “windows” or “apertures”), which, for example, are provided by the intervals 84 between the integrated light concentrating layer 80 and the conductive interconnects 18, where the intervals 84 are filled by cover mask 20 material or encapsulant material 16 in various embodiments. The intervals 84 provide an area free of metallic layers or coatings, thus allowing moisture permeability through the intervals 84. Thus the intervals 84 provide the unexpected, fruitful and unusual result of serving multiple functions: (1) providing an electrically insulating separation between the conductive interconnects 18 and the integrated light concentrating layer 80A, and (2) providing an area of moisture permeability between the encapsulant layers 16 and the flexible electrical backplane 14.

In one embodiment, moisture control is provided by the encapsulant segment 94 shown in FIG. 11, which is a segment of clear encapsulant (one that does not include a metallic reflective layer or reflective particles). The encapsulant segment 94 allows for the movement of moisture through encapsulant layers 16 through the flexible electrical backplane 14 (in areas where there are no metallic or other impermeable conductive interconnects 18) and any back cover (for example, backskin) 54 to and from the exterior of the light concentrating solar module 70. Thus the encapsulant segment 94 provide the unexpected, fruitful and unusual result of serving multiple functions: (1) one function is providing a necessary encapsulant layer underneath the solar cell 12, and (2) the other function is providing an area of moisture permeability between the encapsulant layers 16 and the flexible electrical backplane 14.

If the moisture permeability is too high, then corrosion may occur within the light concentrating module 70 because there is too much moisture; and if the permeability is too low, then corrosion may occur because acetic acid, moisture, and other corrosive molecules cannot migrate out of the module 70. By example, module design and materials are selected depending on their water retention index, moisture permeability and the susceptibility of the materials interior to the module to produce byproducts through the action of UV radiation and temperature excursions, which then may subsequently combine with water to degrade module properties. Water vapor also affects the integrity of the bond between various sheet materials in a light concentrating solar module 70 and the strength of the interface bonding to glass (for example, bonding of the encapsulant layer 16C to a glass front cover 62). The most common encapsulating material, ethyl vinyl acetate (EVA), is typically used under conditions where some water molecule transport through the backskin sheet 54 is permitted. Advantageously, moisture is not trapped, and the moisture and known byproducts of EVA decomposition, such as acetic acid, are allowed to diffuse to prolong module material life; for example, by discouraging EVA discoloration.

In various embodiments of the invention, the backskin 54 material and flexible electrical backplane 14 materials includes a breathable polyvinyl fluoride polymer, other polymer, or other material to form the moisture permeable material, including polymer materials and layered polymer combinations suitable for use with the invention, as well as those to be developed in the future. The flexible electrical backplane 14 provides moisture permeability in areas between the typically metallic materials of the conductive interconnects 18. A typical moisture permeability index or transmissivity which is typical of breathable backskin 54 or flexible electrical backplane 14 material and which is achieved through openings windows 50 and/or intervals 84 between impermeable (for example, metallic) layers is about one gram through about ten grams per square meter per day. It is to be understood that the approach of the invention can also be used for small molecule migration through a backskin 54 and flexible electrical backplane 14 that is permeable to such small molecules.

In some embodiments, the materials of the flexible electrical backplane 14 impedes moisture impermeability, even in areas of the flexible electrical backplane 14 not including metallic conductive interconnects 18. In such a case, perforations in the flexible electrical backplane 14 (not shown in FIG. 8) can be provided typically in areas not including the conductive interconnects 18. In one embodiment, the moisture control feature of the invention is in a range of about 10 to about 1000 perforations per square centimeter. In various embodiments, the perforations can vary in size, and in one embodiment can range from about one micron to about 10 microns in diameter for different embodiments. In various embodiments the total area of the perforations ranges from about 0.1 to 1 percent of the total surface area of the flexible electrical backplane 14. In various embodiments, the amount of perforations varies according to the moisture permeability of the flexible electrical backplane 14 and the backskin 54. In various embodiments, the perforations have various dimensions or shapes (for example, circular, oval, square, rectangular, or other shapes).

The additional encapsulant layer 16C is composed of one or more additional layers of encapsulant (for example, EVA). In one embodiment, the additional encapsulant 16C is composed of ten layers of encapsulant, each layer having a height of about 0.5 millimeters, so that the additional encapsulant 16C is about 5 millimeters in thickness. In one embodiment, the additional encapsulant layer 16C is provided as one relatively thick layer in place of multiple thin layers (such as thin 0.5 millimeter layers); for example, as one encapsulant layer having a thickness of about 5 millimeters. In some embodiments, the additional encapsulant layer 16C is optional. The additional encapsulant 16C provides the unexpected, fruitful, and unusual result of serving two functions: (1) increasing the optical interface distance 86, which is the distance between the optical interfaces (that is, light ray 78 affecting interface usually located at the surface of a layer) which are the top surface 74 of the front cover 62 and the top surface of any light concentrating layer 80 (for example, the top surface 82 of the integrated light concentrating layer 80A), and (2) providing a weight mitigating function that provides encapsulating material in the additional encapsulant layer 16C that does not require a thicker front cover 62 of denser material (for example, glass) or replaces a thick front cover 62 with less dense encapsulating material, allowing a thinner front cover 62.

Regarding the function of increasing the optical interface distance 86, the increased distance 86 enables the light ray 78 to travel farther in a horizontal direction (as shown in FIG. 8) before striking the front surface 11 of a solar cell 12, and thus the solar cells 12 can be spaced farther apart. In one embodiment, the spacing of the solar cells 12 are about 50 percent to about 75 percent of the width of the solar cells 12. It is to be understood that solar cells 12 of various sizes and shapes can be used in various embodiments of the invention. The solar cells 12 can be square, or rectangular in shape, as well as circular and other geometric shapes.

Thus, when providing additional encapsulant 16C, the solar cells 12 can be farther apart, while still providing a light concentrating effect of light rays 78 incident on the solar cells 12. Thus, the same performance (or nearly the same performance) of a module 70 can be maintained while decreasing the number of solar cells 12, which are the most expensive component of the light concentrating solar module 70, and which are, in some time periods, subject to a shortage of supply.

The critical optical interface, in one embodiment, is the top surface 82 of the integrated light concentrating layer 80A, which means the top of the typically metallic surface which provides a reflecting surface that redirects the light ray 78. The top surface 82 may be coated or otherwise provided with a transparent electrically insulating layer (not shown in FIG. 8) which does not substantially affect the passage of the light ray 78. Also, in some embodiments, the integrated light concentrating layer 80A is covered or protected by a cover or mask layer 20, which does not substantially affect the passage of the light ray 78.

Regarding the function of weight mitigation, the additional encapsulant layer 16C is a material, such as a polymeric or ionomer material (for example, a polymer such as EVA), that is less dense than the materials typically used in the front cover 62 (for example, glass). Weight mitigation features suitable for use with the invention are discussed in U.S. Published Patent Application 2008/0185033 by Juris P. Kalejs, the contents of which are incorporated herein by reference.

For example, if more encapsulant material can be used (in layer 16C), and a thinner glass cover 62 can be used, the result is a weight mitigation occurs that reduces the overall weight of the module 70.

In various embodiments of the invention, the front cover 62 ranges in thickness from one millimeter to ten millimeters in thickness. In other embodiments of the invention, the front cover 62 ranges in thickness from about ⅛ inch to about ¼ of an inch in thickness. In other preferred embodiments, the front cover 62 ranges in thickness from about 3 millimeters to about 6 millimeters in thickness.

In various embodiments of the invention, the additional encapsulant layer 16A ranges in thickness from about one-half millimeter to about 10 millimeters. In one embodiment, the front cover 62 has a thickness of about 3 millimeters to about 6 millimeters and the additional encapsulant layer 16C has a thickness of about 2 millimeters to about 6 millimeters. The additional encapsulant layer 16C, in another embodiment, includes six sheets of EVA, each sheet having a thickness of about one-half millimeter. In another embodiment, the front cover 62 has a thickness of about 2 millimeters and the weight mitigation layer 52 has a thickness of about 5 millimeters.

The weight mitigation aspect of the invention retains the advantages of a glass cover (for transparency, resistance to degradation, protection of the front of the module, moisture impermeability that does not transmit water, and hardness (scratch resistance)) while limiting the thickness (and weight) of the front cover 62. Generally, the weight mitigation aspect of the invention also provides the unexpected result of increased reliability, because there are fewer solar cells 12. The weight mitigation approach of the invention also provides the unplanned and fruitful result of providing more U-V (ultraviolet) protection to components (for example, integrated light concentrating layer 80) below the additional encapsulant layer 16C, because the increased polymer layer (for example, EVA) typically has U-V blocking or absorbing properties.

FIG. 9 is a side view of a light concentrating module 70 with a patterned light concentrating layer 80B, in accordance with the principles of the invention. The patterned light concentrating layer 80B, in one embodiment, is a layer that is separate from the flexible electrical backplane 14, and disposed adjacent to the front surface 72 of the backplane 14. In another embodiment, the patterned light concentrating layer 80B is combined or preassembled with the flexible electrical backplane 14. For example, the patterned light concentrating layer 80B is bonded to the front surface 72 of the flexible electrical backplane 14 to form a composite flexible electrical backplane 96, before assembly of the light concentrating solar module 70.

The patterned light concentrating layer 80B is a light concentrating or light redirecting layer that can use any or all of the optical properties of reflecting, refracting, light scattering, light diffusion, and/or diffraction. In various embodiments, the light concentrating layer 80B is a reflective layer (for example, metallic reflective layer or coating), a grooved layer (optionally coated with a metallic reflective layer), a diffractive layer (optionally coated with a metallic reflective layer) including a computer generated optical, kinoform, and/or holographic layer, a particle layer including pigmented, reflective, and/or other particles with light ray 78 affecting optical properties (for example, transparent polymeric layer including particles), or a white or lightly colored layer (for example, white polymeric layer).

For some patterned light concentrating layers 80B, such as transparent layers 80B including optical particles, the optical interactions with the light ray 78 can occur a slight distance within the layer 80B, because a light ray 78 passes through the top surface 88 of the light concentrating layer 80B and interacts with the particles below the top surface 88 before the light ray 78 is directed toward the front cover 62 and passes through the top surface 88 of the light concentrating layer 80B. In some embodiments, the patterned light concentrating layer 80B is transparent and has an optical layer located at the back surface 90 of the patterned light concentrating layer 80B, such as a reflective surface, a grooved or patterned surface, or a diffractive surface. In the case where the optical layer is located at the back surface 90, then the optical interface distance 86 is viewed as extending to the back surface 90 of the patterned light concentrating layer 80B.

FIG. 10 is an overhead plan view of a patterned light concentrating layer 80B1 with apertures 92, in accordance with the principles of the invention (light concentrating layer 80B referring generally to patterned light concentrating layers 80B1 of FIGS. 10 and 80B2 of FIG. 11). The light concentrating layer 80B1 is patterned, because it provides a pattern of apertures 92, which are punched out, cut out, or otherwise manufactured, to maintain an exposure of the interconnect pads 24 to align with the back contacts 26 on the back surfaces 13 of the solar cells 12. In the embodiment shown in FIG. 10, the apertures 92 are longitudinal or rectangular in shape to maintain the exposure of the interconnect pads 24 to align with the back electrical contacts 26 that are similarly shaped; for example, the back contacts 26 extend along the back surface 13 of each solar cell 12 and are disposed next to two sides of the solar cell 12, one back electrical contact extending along each side (of two sides) of the solar cell 12. The pattern of apertures 92 shown in FIG. 10 is not meant to be limiting of the invention, and other patterns of apertures 92 can be used to accommodate other patterns of back contacts 26 to maintain the exposure of the interconnect pads 24 to align with the back contacts 26, in various embodiments of the invention. The apertures 92 are meant to provide access between the conductive interconnects 18 of the flexible electrical backplane 14 and the back contacts 26 of the back surface 13 of the solar cells 12 (which are connected by interconnect attachments 22 during the manufacturing of the light concentrating solar module 70). The solar cell outline 98 shown in FIGS. 10 and 11 indicates the alignment of the solar cell 12 with respect to the apertures 92. FIG. 10 is not meant to be limiting of the extent of the patterned light concentrating layer 80B1, or the number of solar cells 12 associated with a layer 80B1.

The patterns of apertures 92 shown in FIG. 10 is suitable for a moisture permeable patterned light concentrating layer 80B1, for example, if the layer 80B1 is composed of transparent encapsulant (for example, EVA) including light redirecting particles. In one embodiment, the particles in the patterned light concentrating layer 80B1 do not interfere with the transport of moisture and the patterned light concentrating layer 80B1 extends underneath the solar cells 12, and the light concentrating layer 80B1 also serves as the encapsulating layer that is required underneath each solar cell 12. In other embodiments, additional pieces, strips of encapsulant 56 (see FIG. 6B), or encapsulant segments 94 (see FIG. 11) can be provided underneath each solar cell 12 to insure that an adequate amount of encapsulant is provided underneath each solar cell 12.

In another embodiment, the patterned light concentrating layer 80B1, can be overlaid with a clear encapsulant layer, which means one without particles, for example, underlay encapsulant layer 16A (not shown in FIG. 10). The underlay encapsulant layer 16A, in this embodiment, is included to insure that there is an adequate amount of encapsulant underneath each solar cell 12. In such an embodiment, the encapsulant layer (for example, 16A) is patterned in the same manner as shown in FIG. 10 for the patterned light concentrating layer 80B1.

The patterned light concentrating layer 80B1, in one embodiment, is provided as a separate sheet or layer in the manufacturing process, for example, fed onto a layup station from a roll of patterned light concentrating layer 80B1 material. In another embodiment, the patterned light concentrating layer 80B1 is bonded or otherwise preassembled with the flexible electrical backplane 14, for example, bonded to the front surface 72 of the flexible electrical backplane 14 to form a composite flexible electrical backplane 96.

FIG. 11 is an overhead plan view of a patterned light concentrating layer 80B2 with apertures 92 and an encapsulant segment 94, in accordance with the principles of the invention. The patterned light concentrating layer 80B2 includes a surrounding portion 93 and an encapsulant segment 94. The apertures 92, in FIG. 11, are formed by the surrounding portion 93 of the patterned light concentrating layer 80B2 and the encapsulant segment 94, which is located underneath the solar cell 12 after the manufacturing of the light concentrating solar module 70. In one embodiment, the encapsulant segment 94 is composed of clear encapsulant; not including reflective particles, light redirecting layers, or other light redirecting mechanisms. The arrangement of apertures 92, surrounding portion 93, and encapsulant segment 94 shown in FIG. 11 is not meant to be limiting of the invention, and other arrangements of apertures 92, surrounding portion 93, and encapsulant segments 94 can be used to accommodate various patterns of back contacts 26, in various embodiments of the invention to maintain the exposure of the interconnect pads 24 to align with the back contacts 26. The apertures 92 are meant to provide access between the conductive interconnects 18 of the flexible electrical backplane 14 and the back contacts 26 of the back surfaces 13 of the solar cells 12. The solar cell outline 98 shown in FIG. 11 indicates the alignment of the solar cell 12 with respect to the apertures 92. FIG. 11 is not meant to be limiting of the extent of the patterned light concentrating layer 80B2, or the number of solar cells 12 associated with a layer 80B2.

The arrangement of apertures 92 shown in FIG. 11 is suitable for a patterned light concentrating layer 80B2 that is not moisture permeable in the areas represented by the surrounding portion 93; for example, if the surrounding portion 93 of the layer 80B2 is includes one or more metallic layers or coatings that are moisture impermeable. The encapsulant segment 94 of clear encapsulant provides for an adequate amount of encapsulant that is moisture permeable underneath each solar cell 12.

In another embodiment, the patterned light concentrating layer 80B2 can be overlaid with a clear encapsulant layer, which means one without particles, for example, underlay encapsulant layer 16A (not shown in FIG. 11). The underlay encapsulant layer 16A, in this embodiment, is included to insure that there is an adequate amount of encapsulant underneath each solar cell 12. In such an embodiment, the encapsulant layer (for example, 16A) is patterned in the same manner as shown in FIG. 10 or 11 for the patterned light concentrating layer 80B2.

The patterned light concentrating layer 80B2 including the surrounding portion 93 and the encapsulant segment 94, in one embodiment, is provided as a separate sheet or layer in the manufacturing process, for example, fed onto a layup station from a roll of patterned light concentrating layer 80B2 material. In another embodiment, the patterned light concentrating layer 80B2 including the surrounding portion 93 and the encapsulant segment 94, is bonded or otherwise preassembled with the flexible electrical backplane 14; for example, bonded to the front surface 72 of the flexible electrical backplane 14 to from a composite flexible electrical backplane 96.

In various embodiments the encapsulant segment 94 can be either larger or smaller than what is shown in FIG. 11. In one embodiment, the encapsulant segment 94 is larger than the solar cell 12 and extends beyond the edges of the solar cell 12 to ensure a pathway for moisture to and from the overlay encapsulant (other encapsulant layers 16B and 16C).

In other embodiments, the surrounding portion 93 is an encapsulant layer that includes a light redirecting layer disposed at the back surface of the surrounding portion 93. In this embodiment, the encapsulant segment 94 is not extended because moisture can travel to and from the encapsulant layer of the surrounding portion 93 and the encapsulant segment 94.

FIG. 12 is a flowchart of a module fabrication procedure 300 utilizing a flexible electrical backplane 14 and light concentrating layer 80, with soldering and underlay curing, in accordance with the principles of the invention. In step 302, the PV cells 12 are fixtured or placed onto an automated pick and place robotic device to provide for an automated placement of the cells 12 onto the partially assembled module in a later step of the procedure (see step 310). Then, the flexible electrical backplane 14 is fed or positioned onto a table or planar surface (not shown in FIG. 12) of an assembler device. For example, the flexible electrical backplane 14 is unrolled in an automated process onto the table from a roll of backplane 14 material attached to or available to the assembler device.

In one embodiment, the flexible electrical backplane 14 includes an integrated light concentrating layer 80A. In another embodiment, the flexible electrical backplane 14 is bonded or preassembled with a patterned concentrating light layer 80B to form a composite flexible electrical backplane 96 (see FIG. 9), and the composite flexible electrical backplane 96 is unrolled in an automated process onto the table from a roll of composite flexible electrical backplane 96 material.

In one embodiment, the backplane material (for example, 14 or 96) material is automatically sized to a predetermined size (for a given size module). For example, the backplane material (for example, 14 or 96) is cut to the appropriate predetermined size. In another embodiment, the singulation of the module or partially assembled module occurs at step 318 of the procedure 300.

In step 306, in one embodiment, the procedure 300 provides a patterned light concentrating layer 80B, which can be a layer provided as a separate layer, for example, by layering or feeding the layer 80B onto the flexible electrical backplane 14.

In other embodiments, steps 304 and 306 can be combined (not shown in FIG. 12) by feeding the flexible electrical backplane 14 and patterned light concentrating layer 80B concurrently from feeder rolls of material. In one embodiment, three rolls of material are available to the assembler device. One roll is a back cover (for example, 54 in FIG. 8), another roll is the flexible electrical backplane 14 material, and another roll is a patterned light concentrating layer 80B. These rolls are automatically and concurrently fed into the assembler so that the back cover 54 (for example, backskin), is the bottom layer, the flexible electrical backplane 14 material is the middle layer, and the patterned light concentrating layer 80B is the top layer. Then the three layers are sized to a predetermined size, in one embodiment. In other embodiments, additional rolls of encapsulant material can be provided to provide a back encapsulant layer 52 and/or underlay encapsulant layer 16A.

In one embodiment, two rolls of material are provided, if the flexible electrical backplane 14 is capable of serving as the back cover. The two rolls of material are the flexible electrical backplane 14 and the patterned light concentrating layer 80B. In another embodiment, a third roll of material is included, which is an underlay encapsulant layer 16A.

In one embodiment, the flexible electrical backplane material (for example, 14 or 96) is fed or positioned onto the planar surface of the assembler device as sheets of backplane material. In another embodiment, the flexible electrical backplane material (for example, 14 or 96) is fed from precut rolls of backplane material.

In step 308, the procedure prints a solder paste on the flexible electrical backplane 14; for example in a stencil printing process that applies the solder paste to predetermined portions of the conductive interconnects 18. In one embodiment, the process includes printing or providing a cover coat (or solder mask) 20 before applying the solder paste. The solder paste is applied to form interconnect attachments 22 composed of an interconnect material (for example, solder paste) at predetermined positions that are located to align with the back contacts 26 of the PV cells 12, which occurs during step 310 when the PV cells 12 are placed onto the flexible electrical backplane 14.

In one embodiment, a conductive adhesive or conductive ink can be printed or applied to the flexible electrical backplane 14 to form the interconnect attachments 22. In various embodiments, a syringe and needle approach is used to deposit (or dispense) the interconnect material to form the interconnect attachments 22. A pump or pressure approach is used to apply the interconnect material (for example, solder paste, conductive adhesive, conductive ink, or other suitable material) to the flexible electrical backplane 14.

In step 310, the procedure 300 places the PV cells 12 already fixtured in step 302 onto the flexible electrical backplane 14 so the back contacts 26 on the PV cells 12 align with the interconnect attachments 22. In one embodiment, the placement of the PV cells 12 is performed by an automated pick and place device. In one embodiment, this device is an automated pick and place machine. In another embodiment, this device is a placement robot, for example a gantry robot or XY robot.

In step 312, the procedure 300 mass solders the PV cells 12 to the flexible electrical backplane 14. In one embodiment, heat is provided by an IR (infrared) lamp to melt solder in the interconnect attachments 22. In various embodiments, heat is provided by convection heating, microwave heating, or vapor phase (or vapor phase flow) heating (that is, a liquid vapor at a controlled temperature). In one embodiment a lead free solder is used. In another embodiment, a fluxless solder is used. In another embodiment, the interconnect attachments 22 are a conductive adhesive, and heat is provided to cause the conductive adhesive to set. Generally, the thermal processing of the interconnect attachments 22 is in the range of 80 degrees centigrade to 250 degrees centigrade, which covers a range suitable for various types of solder. In one embodiment, if a solder is used, the solder is a low temperature solder, for example, indium. For conductive adhesive, the thermal processing can be in the range of 80 degrees centigrade to 180 degrees centigrade, with a typical range of 120 degrees centigrade to 150 degrees centigrade.

In step 314, an underlay encapsulant 16A is deposited or dispensed, if an underlay encapsulant layer 16A has not been provided earlier in the procedure 300. In one embodiment, the underlay encapsulant 16A is a liquid encapsulant that is deposited or dispensed in the spaces between the spaced apart solar cells 12 and underneath the solar cells 12, if no encapsulant layer 16A or encapsulant segment 94 was provided underneath the solar cells 12 earlier in the procedure 300, so that the liquid encapsulant 16A flows into spaces underneath the solar cells 12 and between the back surfaces 13 of the solar cells 12 and the flexible electrical backplane 14.

In one embodiment, vertical barriers are placed around the partial module (as assembled in steps 302 through 312) to insure that the liquid encapsulant 16 does not leak out. In one embodiment, the liquid encapsulant is deposited or dispensed by an automated syringe and needle approach, using one or more syringes and needles.

In one embodiment, the liquid encapsulant 16 covers the top or front surface 11 of the PV cells 12; forming a front or top encapsulant layer (for example, see 16B in FIG. 8 and FIG. 9). In one embodiment, a top cover sheet (for example, glass) 62 and/or an additional encapsulant layer 16C is placed on top of the liquid encapsulant or PV cells 12 before the curing step (step 316).

In one embodiment, the underlay encapsulant 16A is one or more sheets of encapsulant material layered under the back surfaces 13 of the PV cells 12 and/or layered beneath the flexible backplane 14. In one embodiment, the flexible substrate 28 has windows 50 as shown for example in FIG. 6A (also termed “openings,” “cut-outs,” or “holes”) for parts of the flexible electrical backplane 14 that do not have conductive interconnects 18 embedded or included in the flexible electrical backplane 14, and, in one embodiment, corresponding windows provided in the light concentrating layer 80. The windows 50 allow for the encapsulant 16 to flow into spaces underneath the PV cells 12 from a back encapsulant layer 52, if an encapsulant segment 94 and/or underlay encapsulant layer 16A is not provided. In one embodiment, a window 50 is provided in place of segment 94.

In step 316, the underlay encapsulant 16A is cured (for example, by UV light, a thermal process, a microwave process, or other suitable process) to cause the encapsulant 16A (for example, liquid encapsulant) to solidify. The windows 50 allow UV light to reach an encapsulant 16A that requires UV light to cure the encapsulant 16A. In one embodiment, UV light is provided oriented toward the back surfaces 13 of the solar cells 12, and is incident on the encapsulant 16A through the windows 50 (for example, before an opaque back cover 54 is applied that would block the transmission of UV light). In one example, the UV light is provided by UV lamps through a transparent planar surface that the partially assembled module (by steps 302 through 314) is disposed upon. In one embodiment, the UV light is provided for about one to about two minutes to accomplish the cure of the encapsulant 16A.

In one embodiment, a UV light approach is used with liquid encapsulant 16 for a partial solar electric module that is assembled in a reverse manner than what is shown in FIG. 8 and FIG. 9 (that is, the PV cells 12 would be at the bottom and the flexible substrate 28 at the top). In this assembly approach, a front cover 62 (for example, glass) is placed on a planar surface of an assembler device, then other layers are placed on the front cover 62; for example, an overlay layer of encapsulant (for example, layers 16C and 16B) followed by PV cells 12. In this approach, interconnect attachments 22 are attached to the exposed conductive back contacts 26 on the back surfaces 13 of the PV cells 12, which is facing upward because this approach has reversed the orientation of the PV cell 12 from what is shown in FIG. 8 and FIG. 9. A flexible backplane 14 with integrated light concentrating layer 80A or composite flexible electrical backplane 96 is provided with a flexible substrate 28 that has one or more windows 50 (see FIG. 6A) in the flexible substrate 28 and corresponding windows in any light concentrating layer 80. In this approach, a liquid encapsulant 16A is provided that flows into the space indicated by the window 50. The liquid encapsulant 16A is cured by UV light provided by UV lamps located to provide the UV light through the window 50 so that the UV light is incident on the liquid encapsulant 16A.

In one embodiment, the underlay encapsulant 16A, as well as light concentrating layer 80 based on an encapsulant (for example, an encapsulant layer including light redirecting particles) can be cured by a thermal process. For example, EVA encapsulant can be cured at about 140 through about 155 degrees centigrade for about 6 minutes, or cured at about 139 degrees centigrade for about 12 minutes. In another embodiment, the underlay encapsulant 16A and any encapsulant-based light concentrating layer 80 is cured by a microwave process.

In another embodiment, if a front cover (for example glass) 62 is placed over the PV cells 12 and overlay encapsulant (for example, front sheet of encapsulant 16B and additional encapsulant 16C in FIG. 8 and FIG. 9) is provided between the front cover 62 and the PV cells 12, before step 316, then the front cover 62 can be bonded to the encapsulant 16C by the curing process of step 316. In this approach, a light concentrating solar module 70, as shown for example in FIG. 8 and FIG. 9, is produced.

In step 318, the procedure 300 singulates the concentrator subassembly 97 for module assembly. The concentrator subassembly 97 includes the flexible electrical backplane 14 attached (for example, soldered) to the PV cells 12, light concentrating layer 80, and the cured encapsulant 16A. The concentrator subassembly 97, in one embodiment, can then be transferred to a module assembly or lay-up station where further layers of encapsulant. For example, optional back sheet of encapsulant 52 (not shown in FIG. 8 or FIG. 9) and overlay encapsulant (front encapsulant layer 16B and additional encapsulant 16C) can be added to the concentrator subassembly 97; a back cover 54 (optionally) can be added; and a front cover 62 (for example, glass) can be added. In another embodiment, a back cover 54 (for example, backskin) and layer of encapsulant (for example, back sheet of encapsulant 52 (not shown in FIG. 8 and FIG. 9)) is laid down at a module assembly or lay-up station. Then the concentrator subassembly 97 is next placed at the station, then a further overlay layer of encapsulant (for example, front sheet of encapsulant 16B and additional encapsulant 16C), and then a front cover 62 (for example, glass) to create a layered construct or sandwich. The layered construct or sandwich is then subjected to thermal process, lamination process, and/or other assembly process to form the light concentrating solar module 70.

If a front glass cover 62 has been provided previous to step 318, then a light concentrating solar module 70 has been formed that includes the concentrator subassembly 97. In this case, in step 318, the module 70 is singulated for further processing, which can include adding a frame (of metal or other material) to support and protect the edges of the module and/or attachment of a junction box for electrical connections.

In another embodiment, the flexible electrical backplane 14 can be singulated at an earlier stage of the process, for example, before step 304, when the flexible electrical backplane 14 is separated (for example, cut) from a roll of backplane material used as input to the assembly station.

FIG. 13 is a flowchart of a module fabrication procedure 400 utilizing a flexible electrical backplane 14 and light concentrating layer 80, with thermal processing, in accordance with the principles of the invention. In step 402, the PV cells 12 are fixtured or placed onto an automated pick and place robotic device to provide for an automated placement of the cells 12 onto the partially assembled module in a later step of the procedure 400 (see step 410). Then, in step 404, the procedure 400 feeds the flexible electrical backplane 14 onto a table or planar surface of an assembler device. For example, the flexible electrical backplane 14 is unrolled in an automated process onto the table from a roll of backplane 14 material attached to or available to the assembler device.

In one embodiment, the flexible electrical backplane 14 includes an integrated light concentrating layer 80A. In another embodiment, the flexible electrical backplane 14 is bonded or preassembled with a patterned concentrating light layer 80B to form a composite flexible electrical backplane 96 (see FIG. 9), and the composite flexible electrical backplane 96 is unrolled in an automated process onto the table from a roll of composite flexible electrical backplane 14 material.

In one embodiment, the backplane material (for example, 14 or 96) material is automatically sized to a predetermined size (for a given size module), for example, the backplane material (for example, 14 or 96) is cut to the appropriate predetermined size. In another embodiment, the singulation of the module or partially assembled module occurs at step 416 of the procedure 400.

In another step (step 406) the procedure 400 provides a patterned light concentrating layer 80B, which can be a layer provided as a separate layer, for example, by layering or feeding the layer 80B onto the flexible electrical backplane 14.

In other embodiments, steps 404 and 406 can be combined (not shown in FIG. 13) by feeding the flexible electrical backplane 14 and patterned light concentrating layer 80B concurrently from feeder rolls of material. In one embodiment, three rolls of material are available to the assembler device. One roll is a back cover or backskin (for example, 54 in FIG. 8), another roll is the flexible electrical backplane 14 material, and another roll is for the patterned light concentrating layer 80B. These rolls are automatically and concurrently fed into the assembler so that the back cover 54 (for example, backskin), is the bottom layer, the backplane 14 material is the middle layer, and the patterned light concentrating layer 80B is the top layer. Then the three layers are sized to a predetermined size, in one embodiment. In other embodiments, additional rolls of encapsulant material can be provided to provide a back encapsulant layer 52 and/or underlay encapsulant layer 16A.

In one embodiment, two rolls of material are provided, if the flexible electrical backplane 14 is capable of serving as the back cover. The two rolls of material are the flexible electrical backplane 14 and the patterned light concentrating layer 80B. In another embodiment, a third roll of material is included, which is an underlay encapsulant layer 16A.

In one embodiment, the flexible electrical backplane material (for example, 14 or 96) is fed or positioned onto the planar surface of the assembler device as sheets of backplane material. In another embodiment, the flexible electrical backplane material (for example, 14 or 96) is fed from precut rolls of backplane material.

In step 408, the procedure 400 applies interconnect attachments 22 to predetermined portions of the conductive interconnects 18. In one embodiment, the process includes printing or providing a cover coat (or solder mask) 20 before applying an interconnect material that forms the interconnect attachments 18. The interconnect material, in various embodiments, can be a conductive adhesive or conductive ink. In other embodiments, the interconnect material is a metal particle material. In one embodiment, the process includes printing or providing a cover coat (or solder mask) 20 before applying the interconnect material. In one embodiment, the interconnect material is a solder or solder paste. The interconnect material is applied to form interconnect attachments 22 at predetermined positions that are located to align with the back contacts 26 of the PV cells 12, which occurs during step 410 when the PV cells 12 are placed onto the flexible electrical backplane 14.

In various embodiments, a syringe and needle approach is used to deposit or dispense the interconnect material to form the interconnect attachments 22. A pump or pressure approach is used to apply the interconnect material (for example, conductive adhesive) to the flexible electrical backplane 14.

In step 410, the procedure 400 places the PV cells 12 already fixtured in step 402 onto the flexible electrical backplane 14 so the back contacts 26 on the PV cells 12 align with the interconnect attachments 22. In one embodiment, the placement of the PV cells 12 is performed by an automated pick and place device. In one embodiment, this device is an automated pick and place machine. In another embodiment, this device is a placement robot, for example a gantry robot or XY robot.

In step 412, an underlay encapsulant 16A is provided. In one embodiment, the underlay encapsulant 16A is one or more sheets of encapsulant material layered under the back surfaces 13 of the PV cells 12 or encapsulating layer 52 layered beneath the flexible backplane 14. In one embodiment, the flexible substrate 28 has windows 50, as shown for example in FIG. 6A (also termed “openings,” “cut-outs,” or “holes”) in parts of the flexible electrical backplane 14 that do not have conductive interconnects 18 embedded or included in the flexible electrical backplane 14. In one embodiment, the windows 50 are aligned with the encapsulant segments 94 of a patterned light concentrating layer 80B2 (see FIG. 11). The windows 50 allow for the encapsulant 16 (for example, from encapsulating layer 54) to flow into spaces underneath the PV cells 12 when the thermal process is applied (step 414), if an encapsulant segment 94 and/or underlay encapsulant layer 16A is not provided. In one embodiment, a window 50 is provided in place of segment 94.

In one embodiment, the underlay encapsulant 16A is a liquid encapsulant that is deposited or dispensed in the spaces between the spaced apart solar cells 12 and underneath the solar cells 12, if no encapsulant layer 16A or encapsulant segment 94 was provided underneath the solar cells 12 earlier in the procedure 400, so that the liquid encapsulant 16A flows into spaces underneath back surfaces 13 of the solar cells 12 and between the solar cells 12 and the flexible electrical backplane 14. In one embodiment, vertical barriers are placed around the partial module (as assembled in steps 402 through 410) to insure that the liquid encapsulant 16 does not leak out. In one embodiment, the liquid encapsulant is deposited or dispensed by an automated syringe and needle approach, using one or more syringes and needles.

In another embodiment, a liquid encapsulant is provided for the underlay encapsulant 16A before the placement of the photovoltaic cells 12 (that is, before step 410) and after the provision of the light concentrating layer 80, and the liquid encapsulant is cured by the application of UV light. The interconnect attachments 22 can be covered with a mask material to prevent the interconnect attachments 22 from being covered with encapsulant 16A, and the mask material must be removed before the placement of the photovoltaic cells 12.

In step 414, the underlay encapsulant 16A is cured by applying a thermal process (for example, by infrared light), a microwave process, a UV light process, or other suitable curing process. The thermal or microwave process causes the encapsulant 16A to flow (if in the form of sheets and/or encapsulant segments 94) material to fill the spaces underneath the PV cells 12 (that is, between the PV cells 12 and the conductive interconnects 18). In a substantially simultaneous process, the thermal or microwave process causers the PV cells 12 to bond to the flexible electrical backplane 14. In one embodiment, the thermal or microwave process causes a thermosetting conductive adhesive to set. In another embodiment, a UV light process causes the encapsulant 16A (for example, liquid encapsulant) to set. In another embodiment, a UV light process causes the conductive adhesive or conductive ink to set.

In another embodiment, the underlay encapsulant 16A is first treated with UV light to initiate a curing process (for example, for a liquid encapsulant 16), and then the curing is completed with a thermal process. In another embodiment, step 414 includes the application of pressure as well as other processes (for example, a thermal, microwave, and/or UV light process).

In one embodiment, if a front cover (for example glass) 62 is placed over the PV cells 12 and a front encapsulant layer 16B and additional encapsulant layer 16C is provided between the front cover 62 and the PV cells 12, before step 414, then the front cover 62 can be bonded to the additional encapsulant 16C by the thermal process of step 414. In this approach, a light concentrating module 70, as shown for example in FIG. 8 and FIG. 9, is produced.

In step 416, the procedure 400 singulates the concentrator subassembly 97 for module assembly. The concentrator subassembly 97 includes the flexible electrical backplane 14 attached (for example, soldered) to the PV cells 12, the light concentrating layer 80, and the cured encapsulant 16A. The concentrator subassembly 97, in one embodiment, can then be transferred to a module assembly or lay-up station where additional layers of encapsulant. For example, optional back sheet of encapsulant 52 (not shown in FIG. 8 or FIG. 4), and overlay encapsulant (front sheet of encapsulant 16B, and additional encapsulant 16C) can be added to the top and/or back of the concentrator assembly 97; a back cover 54 (optionally) can be added; and a front cover 62 (for example, glass) can be added. In another embodiment, a back cover 54 (for example, backskin) and layer of encapsulant (for example, back sheet of encapsulant 52) are laid down at a module assembly or lay-up station. Then the concentrator subassembly 97 is next placed at the station, then a further layer of overlay encapsulant (for example, front sheet of encapsulant 16B and additional encapsulant layer 16C), and then a front cover 62 (for example, glass) to create a layered construct or sandwich. The layered construct or sandwich is then subjected to thermal process, lamination process, and/or other assembly process to form the light concentrating module 70 (see FIG. 8 and FIG. 9).

If a front glass cover 62 has been provided previous to step 414, then a light concentrating module 70 has been formed that includes the concentrator subassembly 97. In this case, in step 416, the module 70 is singulated for further processing, which can include adding a frame (of metal or other material) to support and protect the edges of the module and/or attachment of a junction box for electrical connections.

In another embodiment, the flexible electrical backplane 14 can be singulated at an earlier stage of the process, for example, before step 406, when the flexible electrical backplane 14 is separated (for example, cut) from a roll of backplane material used as input to the assembly station.

The procedures 300 described in FIGS. 12 and 400 described in FIG. 13 can be, in one embodiment, a discrete panel process, in which discrete concentrator subassemblies 97 or light concentrating modules 70 are produced. In various embodiments, the procedures 300 and 400 can be adapted to a continuous flow manufacturing approach in which backplane material (for example, 14 or 96) is input from a roll in a continuous manner, other layers can optionally be input from one or more rolls, and concentrator subassemblies 97 (or complete light concentrating modules 70) are separated at the end of a continuous processing line.

Having described the preferred embodiments of the invention, it will now become apparent to one of skill in the arts that other embodiments incorporating the concepts may be used. It is felt, therefore, that these embodiments should not be limited to the disclosed embodiments but rather should be limited only by the spirit and scope of the following claims.

What is claimed is:

1. A method of fabricating a light concentrating solar module having a plurality of photovoltaic cells, each photovoltaic cell having a plurality of conductive contacts located on a back surface of each photovoltaic cell, the method comprising:
feeding a flexible electrical backplane onto a planar surface, said flexible electrical backplane comprising a flexible substrate and a light concentrating layer disposed adjacent to a front surface of said flexible substrate, said flexible electrical backplane having preformed conductive interconnects in contact with interconnect pads exposed on a front surface of said flexible electrical backplane at predetermined locations;
forming a plurality of interconnect attachments in electrical contact with said exposed interconnect pads based on applying an interconnect material onto said exposed interconnect pads;
placing said conductive contacts of said photovoltaic cells in an alignment with said predetermined locations of said interconnect pads and in contact with said interconnect attachments, said predetermined locations determined to provide said alignment for said interconnect pads, said interconnect attachments, and said conductive contacts;
providing an underlay encapsulant to fill a plurality of spaces formed between said back surfaces of said photovoltaic cells and said front surface of said flexible substrate; and
applying a curing process to said underlay encapsulant solidifying said underlay encapsulant and to said interconnect attachments forming a conductive path from each conductive contact through a respective one of said interconnect attachments to a respective one of said interconnect pads.

2. The method of claim 1, wherein said light concentrating layer is a light reflecting metallic material.

3. The method of claim 1, wherein said light concentrating layer comprises a diffractive material.

4. The method of claim 1, wherein said light concentrating layer comprises light redirecting grooves.

5. The method of claim 1, wherein said light concentrating layer comprises a transparent material comprising light redirecting particles.

6. A method of fabricating a light concentrating solar module having a plurality of photovoltaic cells, each photovoltaic cell having a plurality of conductive contacts located on a back surface of each photovoltaic cell, the method comprising:
feeding a flexible electrical backplane comprising a flexible substrate onto a planar surface, said flexible electrical backplane having preformed conductive interconnects in contact with interconnect pads exposed on a front surface of said flexible substrate at predetermined locations;
providing a light concentrating layer disposed adjacent to said front surface of said flexible substrate, said light concentrating layer configured to maintain an exposure of said interconnect pads;
forming a plurality of interconnect attachments in electrical contact with said exposed interconnect pads based on applying an interconnect material onto said exposed interconnect pads;
placing said conductive contacts of said photovoltaic cells in an alignment with said predetermined locations of said interconnect pads and in contact with said interconnect attachments, said predetermined locations determined to provide said alignment for said interconnect pads, said interconnect attachments, and said conductive contacts;
providing an underlay encapsulant to fill a plurality of spaces formed between said back surfaces of said photovoltaic cells and said front surface of said flexible substrate; and
applying a curing process to said underlay encapsulant solidifying said underlay encapsulant and to said interconnect attachments forming a conductive path from each conductive contact through a respective one of said interconnect attachments to a respective one of said interconnect pads.

7. The method of claim 6, wherein said feeding said flexible electrical backplane comprises feeding said flexible electrical backplane from a roll of backplane material and said providing said light concentrating layer comprises feeding said light concentrating layer from a roll of light concentrating material.

8. The method of claim 6, wherein said light concentrating layer is a light reflecting metallic material.

9. The method of claim 6, wherein said light concentrating layer comprises a diffractive material.

10. The method of claim 6, wherein said light concentrating layer comprises light redirecting grooves.

11. The method of claim 6, wherein said light concentrating layer comprises a transparent material comprising light redirecting particles.

12. The method of claim 6, said light concentrating layer having a predetermined pattern of apertures aligned to maintain said exposure of said interconnect pads.

13. The method of claim 6, said light concentrating layer comprising a plurality of encapsulant segments aligned to maintain said exposure of said interconnect pads.

14. A method of fabricating a light concentrating solar module having a plurality of photovoltaic cells, each photovoltaic cell having a plurality of conductive contacts located on a back surface of each photovoltaic cell, the method comprising:
feeding a flexible electrical backplane onto a planar surface, said flexible electrical backplane comprising a flexible substrate and a light concentrating layer disposed adjacent to a front surface of said flexible substrate, said flexible electrical backplane having preformed conductive interconnects in contact with interconnect pads exposed on a front surface of said flexible electrical backplane at predetermined locations;
forming a plurality of interconnect attachments in electrical contact with said exposed interconnect pads based on applying an interconnect material onto said exposed interconnect pads;
placing said conductive contacts of said photovoltaic cells in an alignment with said predetermined locations of said interconnect pads and in contact with said interconnect attachments, said predetermined locations determined to provide said alignment for said interconnect pads, said interconnect attachments, and said conductive contacts;
applying a thermal process to said interconnect attachments forming a conductive path from each conductive contact through a respective one of said interconnect attachments to a respective one of said interconnect pads;
depositing a liquid underlay encapsulant flowing to fill a plurality of spaces formed between said back surfaces of said photovoltaic cells and said front surface of said flexible substrate; and
applying a curing process to said liquid underlay encapsulant solidifying said liquid encapsulant.

15. The method of claim 14, wherein said light concentrating layer is a light reflecting metallic material.

16. The method of claim 14, wherein said light concentrating layer comprises a diffractive material.

17. The method of claim 14, wherein said light concentrating layer comprises light redirecting grooves.

18. The method of claim 14, wherein said light concentrating layer comprises a light transparent material comprising light redirecting particles.

19. A method of fabricating a light concentrating solar module having a plurality of photovoltaic cells, each photovoltaic cell having a plurality of conductive contacts located on a back surface of each photovoltaic cell, the method comprising:
feeding a flexible electrical backplane comprising a flexible substrate onto a planar surface, said flexible electrical backplane having preformed conductive interconnects in contact with interconnect pads exposed on a front surface of said flexible substrate at predetermined locations;
providing a light concentrating layer disposed adjacent to said front surface of said flexible substrate, said light concentrating layer configured to maintain an exposure of said interconnect pads;
forming a plurality of interconnect attachments in electrical contact with said exposed interconnect pads based on applying an interconnect material onto said exposed interconnect pads;
placing said conductive contacts of said photovoltaic cells in an alignment with said predetermined locations of said interconnect pads and in contact with said interconnect attachments, said predetermined locations determined to provide said alignment for said interconnect pads, said interconnect attachments, and said conductive contacts;
applying a thermal process to said interconnect attachments forming a conductive path from each conductive contact through a respective one of said interconnect attachments to a respective one of said interconnect pads;
depositing a liquid underlay encapsulant flowing to fill a plurality of spaces formed between said back surfaces of said photovoltaic cells and said front surface of said flexible substrate; and
applying a curing process to said liquid underlay encapsulant solidifying said liquid encapsulant.

20. The method of claim 19, wherein said feeding said flexible electrical backplane comprises feeding said flexible electrical backplane from a roll of backplane material and said providing said light concentrating layer comprises feeding said light concentrating layer from a roll of light concentrating material.

21. The method of claim 19, wherein said light concentrating layer is a light reflecting metallic material.

22. The method of claim 19, wherein said light concentrating layer comprises a diffractive material.

23. The method of claim 19, wherein said light concentrating layer comprises light redirecting grooves.

24. The method of claim 19, wherein said light concentrating layer comprises a transparent material comprising light redirecting particles.

25. The method of claim 19, said light concentrating layer having a predetermined pattern of apertures aligned to maintain said exposure of said interconnect pads.

26. The method of claim 19, said light concentrating layer comprising a plurality of encapsulant segments aligned to maintain said exposure of said interconnect pads.

27. A light concentrating solar module comprising:
a transparent front cover having a front surface and a back surface;
a plurality of photovoltaic cells; each photovoltaic cell having one front surface facing said transparent front cover and one back surface facing away from said transparent cove; and each photovoltaic cell having a plurality of back contacts on each back surface thereof;
a back cover spaced apart from and substantially parallel to said transparent front cover, said plurality of photovoltaic cells disposed between said transparent front cover and said back cover;
a light transmitting encapsulant disposed between said transparent front cover and said back cover;
a light concentrating layer disposed between said photovoltaic cells and said back cover, said transparent front cover transmitting light through said transparent front cover and incident on said light concentrating layer in regions between said photovoltaic cells, said light concentrating layer directing said light towards said transparent front cover, and said front surface of said transparent front cover internally reflecting said light back towards said photovoltaic cells;
a flexible electrical backplane comprising a flexible substrate and a plurality of conductive interconnects preformed thereon in a predetermined pattern; and
a plurality of interconnect attachments each disposed between one of said conductive interconnects and one of said back contacts of one of said photovoltaic cells.

28. The solar module of claim 27, wherein said flexible electrical backplane comprises said light concentrating layer.

29. The solar module of claim 27, wherein said light concentrating layer is provided in said regions between said photovoltaic cells adjacent to said flexible electrical backplane.

30. The solar module of claim 27, wherein said light concentrating layer is a light reflecting metallic material.

31. The solar module of claim 27, wherein said light concentrating layer comprises a diffractive material.

32. The solar module of claim 27, wherein said light concentrating layer comprises light redirecting grooves.

33. The solar module of claim 27, wherein said light concentrating layer comprises a transparent material comprising light redirecting particles.

34. The solar module of claim 27, said flexible substrate having windows disposed adjacent to said back surfaces of said photovoltaic cells, each window adjacent to a respective one of said photovoltaic cells.

35. The solar module of claim 27, said light transmitting encapsulant comprising an overlay layer of transparent material disposed adjacent to said back surface of said transparent front cover and an underlay layer of transparent material disposed adjacent to said back surfaces of said solar cells; said overlay layer of transparent material comprising at least one encapsulating sheet adjacent to said front surfaces of said solar cells, and an additional layer of encapsulant disposed between said back surface of said transparent front cover and said at least one encapsulating sheet; said additional layer having a density less than said transparent front cover, and replacing a volume of said transparent front cover equal to a volume of said additional layer.

36. The solar module of claim 27, wherein said conductive interconnects and said light concentrating layer form intervals between said conductive interconnects and said light concentrating layer, said intervals providing an electrically insulating separation between said conductive interconnects and said light concentrating layer and providing areas of moisture permeability for moisture flow between said light transmitting encapsulant and said flexible electrical backplane.

37. The solar module of claim 27, further comprising encapsulant segments disposed adjacent to the back surfaces of said solar cells, providing encapsulating material adjacent to said solar cells and providing moisture permeability between said light transmitting encapsulant and said flexible electrical backplane.
